(19) United States
(12) Patent Application Publication
(10) Pub. No.: US 2008/0246076 A1
(43) Pub. Date: Oct. 9, 2008

(54) Methods for nanopatterning and production of nanostructures

(75) Inventor: Jian Chen, Mountain View, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: NANOSYS, Inc., Palo Alto, CA (US)

(21) Appl. No.: 12/003,965

(22) Filed: Jan. 3, 2008

Related U.S. Application Data
(60) Provisional application No. 60/878,342, filed on Jan. 3, 2007.
(60) Provisional application No. 60/906,824, filed on Mar. 14, 2007.

(51) Int. Cl. H01L 29/788; B32B 3/10; H01B 13/00; H01L 21/308

(52) U.S. Cl. 257/316; 428/195.1; 216/13; 438/703; 257/E21.31; 257/E29.3

(57) ABSTRACT

Methods for nanopatterning and methods for production of nanoparticles utilizing such nanopatterning are described herein. In exemplary embodiments, masking nanoparticles are disposed on various substrates and to form a nanopatterned mask. Using various etching and filling techniques, nanoparticles and nanocavities can be formed using the masking nanoparticles and methods described throughout.

### CROSS REFERENCE TO RELATED APPLICATIONS

The present application claims priority to U.S. Provisional Patent Application No. 60/878,342, filed Jan. 3, 2007, and U.S. Provisional Patent Application No. 60/906,824, filed Mar. 14, 2007, the disclosures of each of which are incorporated by reference herein in their entireties.

### BACKGROUND OF THE INVENTION

1. Field of the Invention

The present invention relates to methods of nanopatterning using nanoparticles. The present invention also relates to nanostructures, including nanoparticles, produced using the nanopatterning methods, as well as memory and charge storage layers comprising such nanostructures.

2. Background Art

Nanoparticles, including colloidal nanocrystals and nanoparticles, can be readily produced using various chemical syntheses. The use of surface ligands allows the nanoparticles to be readily deposited on various substrates in regular, controlled orientations and spacings. For example, spin-coating on a substrate wafer. Thermal constraints however limit the ability to perform thermal processing techniques to bind or fix the nanoparticles on a substrate (nanoparticles melt at a temperature below the bulk material).

In applications such as flash memory, chemical vapor deposition/physical vapor deposition (CVD/PVD) is often used to deposit a thin layer of material, e.g., metal, on a substrate. Subsequent heating then causes the material to form small droplets. However, this process is thermodynamically controlled and often does not yield uniform, regularly spaced nanoparticles.

What is needed therefore are methods for the production of uniformly-sized nanostructures that can be arranged in a controlled, regular pattern. Nanostructures prepared in such a manner are particularly useful in applications such as charge storage layers in non-volatile memory devices, including flash memory devices.

### BRIEF SUMMARY OF THE INVENTION

The present invention fulfills needs present in the art by providing methods for nanopatterning using masking nanoparticles. These nanopatterning methods can then be used to prepare uniform, regularly-spaced nanostructures from a range of materials and on/in a variety of substrates.

In an embodiment, the present invention provides methods for generating one or more nanostructures of a charge storage layer. In exemplary embodiments, one or more masking nanoparticles are disposed on a charge storage layer substrate, wherein the nanoparticles cover at least a portion of the substrate. Uncovered substrate material is then removed, thereby forming substrate nanostructures at the site of the masking nanoparticles. Finally, the masking nanoparticles are removed revealing the nanostructures.

In exemplary embodiments, the charge storage layer comprises a metal substrate, such as W, WN₂, TaN, or Iridium. Spin coating can be used to dispose the masking nanoparticles, which can comprise Pd, Ni, Ru, Co, or Au nanoparticles, and are suitably between about 1-10 nm, or about 1-5 nm in size. Removing the substrate material is suitably performed using an etching process, such as reactive ion etching or electron beam etching.

In additional embodiments, the present invention provides methods for generating nanoscale cavities in a substrate material. For example, a negative photo-resistant layer is disposed on a substrate, and then one or more masking nanoparticles are disposed on the negative photo-resistant layer, wherein the nanoparticles cover at least a portion of the layer. Uncovered portions of the negative photo-resistant layer are then reacted (e.g., with UV light) to form one or more etch masks comprising one or more portions of reacted negative photo-resistant layer and one or more portions of un-reacted negative photo-resistant layer. The masking nanoparticles are then removed and un-reacted portions of the photo-resistant layer are also removed (e.g., via etching), thereby revealing one or more exposed substrate sections. These exposed substrate sections are then removed, thereby forming nanoscale cavities in the substrate. Nanoscale cavities can be prepared in various substrates, including insulators, such as silicon dioxide. Methods for disposing masking nanoparticles as well as sizes and compositions of the masking nanoparticles are described throughout.

Methods are also provided for generating one or more nanostructures using the nanoscale cavities of the present invention. For example, a filler material (e.g., a metal) is disposed in the nanoscale cavities, and any excess filler material (e.g., that is above the plane of the substrate) is removed, thereby forming one or more nanostructures in the nanoscale cavities.

In a further embodiment, the present invention provides methods for generating one or more nanostructures. One or more masking nanoparticles are disposed on a substrate, wherein the nanoparticles cover at least a portion of the substrate. Uncovered substrate material is then removed, thereby forming substrate pillars at the portion of the substrate covered by the masking nanoparticles, and forming substrate cavities at a portion of the substrate not covered by the masking nanoparticles. The masking nanoparticles are then removed, and an insulating layer is disposed on the pillars and at least partially in the cavities, wherein a pit is maintained at the site of the cavities. Finally, a filler material (e.g. a metal) is disposed on the insulating layer, wherein the filler material forms nanostructures confined to the pits. Exemplary insulating layers include oxide layers that are grown on the substrate.

In exemplary embodiments, the filler material is annealed, for example, by heating the filler material to a temperature greater than the filler material annealing temperature. In further embodiments, the filler material is deposited and then a portion of the filler material and a portion of the insulating layer subsequently removed.

The present invention also provides methods for generating nanoscale cavities in a substrate material. For example, a support structure is provided and one or more masking nanoparticles are disposed on the support structure. Then, a substrate material is disposed on the masking nanoparticles and the support structure, thereby covering the masking nanoparticles. At least a portion of the substrate material is then removed (e.g., via planing or mechanical polishing), thereby revealing at least a portion of the masking nanoparticles. Finally, the masking nanoparticles are removed, thereby forming nanoscale cavities in the substrate material. As discussed above, nanostructures can be prepared by disposing a filler material in the nanoscale cavities produced according to the methods of the present invention. In additional embodiments, the nanoscale cavities can be filled with a phase change material, and phase change memory cells can be produced.

The present invention also provides nanostructures and nanoscale cavities prepared by the various processes of the present invention.

The present invention also provides metallic nanostructures, wherein the nanostructures comprise diameters between about 1 nanometer and about 10 nanometers and with size distributions no greater than about 15% of a mean diameter of the nanostructures. The nanostructures also suitably comprise center-to-center spacing between adjacent nanostructures between about 1 nanometer and about 10 nanometers a variance of about 10%.

In addition, the present invention also provides field effect transistors. Exemplary field effect transistors comprise a source region and a drain region formed in a semiconductor material, as well as a channel region disposed between the source region and the drain region. In addition, an insulating layer of electrically insulating material is disposed over the channel region. A floating gate layer of electrically conducting material is disposed over the insulating layer and a layer of electrically insulating material is disposed over the floating gate layer. In addition, a gate electrode overlies the layer of insulating material. In exemplary embodiments, the floating gate layers of the field effect transistors of the present invention comprise nanostructures of the present invention.

The present invention also provides methods for generating one or more nanowires. As discussed above, one or more masking nanoparticles are disposed on the substrate, wherein the nanoparticles cover at least a portion of the substrate. Uncovered substrate material is then removed, thereby forming substrate nanowires at the site of the masking nanoparticles, wherein the nanowires are greater than 20 nm in length. Finally, the masking nanoparticles are removed.

The present invention also provides methods for generating one or more transistor switches. In such embodiments, one or more masking nanoparticles are disposed on the substrate, wherein the nanoparticles cover at least a portion of the substrate. As noted above, uncovered substrate material is then removed, thereby forming substrate nanowires at the site of the masking nanoparticles. After removal of the masking nanoparticles, a first oxide layer is grown on the substrate and substrate nanowires. Then, a filler material is deposited and then a portion removed, whereby a cavity is formed in the filler material between substrate nanowires. A second oxide layer is then disposed, and finally the first and the second oxide layers are removed, whereby a portion of the substrate nanowires are exposed, and whereby the filler material is not exposed. In exemplary embodiments, the nanowires are n+p−n+ or p+n−p+ doped nanowires, which can be prepared directly from the substrate material, or doping can take place following nanowire formation.

The present invention also provides methods for generating arrays electrically connected transistor switches. Transistor switches in accordance with the present invention are formed. Then, masked and unmasked alternating lines are generated, wherein the lines comprise substrate nanowires and filler material. Unmasked alternating lines are then removed, thereby forming troughs between masked lines. An insulating material is then disposed in the troughs, and portions of the nanowires are exposed. Finally, the filler material and nanowires are electrically connected.

The present invention also provides methods of generating arrays of electrically connected phase change memory (PCM) cells. Arrays of transistor switches as described above are generated, and a phase change material layer is disposed on the nanowires and then the nanowires electrically connected (e.g., via disposing a layer of electrically conducting material on the phase change layer).

The present invention also provides transistor switches comprising one or more transistor nanowires; an electrically conductive gate material surrounding the nanowires; an insulating material separating the nanowires from the electrically conductive gate material; an electrical connection to the gate material; and an electrical connection to the nanowires.

In addition, phase change memory (PCM) cells are provided, comprising one or more transistor nanowires; an electrically conductive gate material surrounding the nanowires; a phase change material layer contacting at least a portion of at least one nanowire; an insulating material separating the nanowires from the electrically conductive gate material, and separating the electrically conductive gate material from the phase change material layer; and an electrical connection to the phase change material layer. The present invention also provides arrays of PCM cells.

Utilization of the PCM cells and arrays of the present invention allows for setting of the cells by heating the phase change material to a temperature above the crystalline temperature of the phase change material, but below the melting point of the phase change material, by passing a current through the phase change material and slowly cooling the phase change material. Resetting of the PCM cells can take place by heating the phase change material to a temperature above the melting point of the phase change material, by passing a current through the phase change element and rapidly cooling the element. In addition, the set and reset states of the PCM cells can be read by passing a current through the PCM cell and measuring the current through the PCM cell, wherein the PCM cell is in a reset state if the current is below a threshold value and in a set state if the current is above the threshold value.

Additional features and advantages of the invention will be set forth in the description that follows, and in part will be apparent from the description, or may be learned by practice of the invention. The advantages of the invention will be realized and attained by the structure and particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIGS. 1A-1C show masking nanoparticles prepared in accordance with one embodiment of the present invention.

FIG. 2 shows a flowchart of a method for generating nanostructures in accordance with one embodiment of the present invention.

FIGS. 3A-3D show a schematic of a method for generating nanostructures in accordance with one embodiment of the present invention.

FIG. 4 shows a flowchart of a method for generating nanoscale cavities in accordance with one embodiment of the present invention.

FIGS. 5A-5F show a schematic of a method for generating nanoscale cavities in accordance with one embodiment of the present invention.

FIG. 6 shows a flowchart of a method for generating nanostructures using nanoscale cavities in accordance with one embodiment of the present invention.

FIGS. 7A-7C show a method for generating nanostructures using nanoscale cavities in accordance with one embodiment of the present invention.

FIG. 8 shows a flowchart of a method for generating nanostructures of a filler material in accordance with one embodiment of the present invention.

FIGS. 9A-9L show a method of generating nanostructures of a filler material in accordance with one embodiment of the present invention.

FIG. 10A shows a flowchart of a method for generating nanoscale cavities in substrate material in accordance with one embodiment of the present invention.

FIG. 10B shows a flowchart of a method for generating nanostructures in accordance with one embodiment of the present invention.

FIG. 10C shows a flowchart of a method for generating a nanoscale phase change layer and a method for generating a phase change memory cell (PCM) in accordance with embodiments of the present invention.

FIGS. 11A-F show a method of generating nanoscale cavities in a substrate material, methods for generating a nanoscale phase change layer, and a methods for generating a phase change memory (PCM) cell in accordance with embodiments of the present invention.

FIG. 12 shows a flowchart of a method of generating one or more transistor switches in accordance with one embodiment of the present invention.

FIGS. 13A-F show a method of generating one or more transistor switches in accordance with one embodiment of the present invention.

FIGS. 14A and 14B show alternative views of transistor switches in accordance with one embodiment of the present invention.

FIG. 15 shows a flowchart of a method of generating an array of electrically connected switches and a method for generating an array of electrically connected PCM cells in accordance with embodiments of the present invention.

FIGS. 16A-D show a method of generating an array of electrically connected switches and a method for generating an array of electrically connected PCM cells in accordance with embodiments of the present invention.

FIGS. 17 A-B show an expanded view of an array of electrically connected PCM cells in accordance with one embodiment of the present invention.

FIGS. 18A-B show a state diagram and exemplary current profiles for PCM cells in accordance with one embodiment of the present invention.

The present invention will now be described with reference to the accompanying drawings. In the drawings, like reference numbers indicate identical or functionally similar elements.

### DETAILED DESCRIPTION OF THE INVENTION

It should be appreciated that the particular implementations shown and described herein are examples of the invention and are not intended to otherwise limit the scope of the present invention in any way. Indeed, for the sake of brevity, conventional electronics, manufacturing, semiconductor devices, and nanocrystal, nanoparticle, nanowire (NW), nanorod, nanotube, and nanoribbon technologies and other functional aspects of the systems (and components of the individual operating components of the systems) may not be described in detail herein. Further, the techniques are suitable for applications in electrical systems, optical systems, consumer electronics, industrial or military electronics, wireless systems, space applications, or any other application.

As used herein, the term “nanostructure” refers to a structure that has at least one region or characteristic dimension with a dimension of less than about 500 nm, including on the order of less than about 1 nm. As used herein, when referring to any numerical value, “about” means a value of ±10% of the stated value (e.g. “about 100 nm” encompasses a range of sizes from 90 nm to 110 nm, inclusive). The term “nanostructure” as used herein encompasses nanoparticles, quantum dots, nanocrystals, nanowires, nanorods, nanoribbons, nanotetrapods and other similar nanostructures known to those skilled in the art. As described throughout, nanostructures (including nanoparticles, nanocrystals, quantum dots, nanowires, etc.) suitably have at least one characteristic dimension less than about 500 nm. Suitably, nanostructures are less than about 500 nm, less than about 300 nm, less than about 200 nm, less than about 100 nm, less than about 50 nm, less than about 20 nm, less than about 15 nm, less than about 10 nm or less than about 5 nm in at least one characteristic dimension (e.g., the dimension across the width or length of the nanostructure).

As used herein, the terms “masking nanoparticle” and “masking nanocrystal” are used interchangeably and refer to nanostructures (e.g., nanocrystals) used to pattern a substrate and subsequently utilized to prepare nanostructures and/or nanoscale cavities.

Typically, the region of characteristic dimension is along the smallest axis of the structure. Masking nanoparticles for use in the present invention are suitably substantially the same size in all dimensions, e.g., substantially spherical, though non-spherical nanoparticles can also be used. Masking nanoparticles can be substantially homogenous in material properties, or in certain embodiments, can be heterogeneous. The optical properties of nanoparticles can be determined by their particle size, chemical or surface composition. The present invention provides the ability to tailor masking nanoparticle size in the range between about 1 nm and about 50 nm (suitably about 1 to 20 nm) allows, although the present invention is applicable to other size ranges of nanoparticles. The term “masking nanoparticles” as used herein also encompasses masking nanocrystals, masking nanowires, masking nanorods, masking nanoribbons, masking nanotetrapods, and other similar nanostructures known to those skilled in the art. As described throughout, nanowires (or similar structures) of the present invention suitably have at least one characteristic dimension less than about 500 nm. Suitably, nanowires of the present invention are less than about 500 nm, less than about 300 nm, less than about 200 nm, less than about 100 nm in diameter, less than about 50 nm in diameter, less than about 20 nm in diameter, or less than abut 10 nm in diameter (i.e. the dimension across the width of the nanowire). Examples of such nanowires include semiconductor nanowires as described in Published International Patent Application Nos. WO 02/17362, WO 02/48701, and WO 01/03208, carbon nanotubes, and other elongated conductive or semiconductive structures of like dimensions.

Masking nanoparticles for use in the present invention can be produced using any method known to those skilled in the art. Suitable methods are disclosed in U.S. patent application Ser. No. 11/034,216, filed Jan. 13, 2005, U.S. patent application Ser. No. 10/796,832, filed Mar. 10, 2004, U.S. patent application Ser. No. 10/656,910, filed Sep. 4, 2003, U.S. Provisional Patent Application No. 60/578,236, filed Jun. 8, 2004, and U.S. patent application Ser. No. 11/506,769, filed Aug. 18, 2006, the disclosures of each of which are incorporated by reference herein in their entireties. The masking nanoparticles for use in the present invention can be produced from any suitable material, including an inorganic material, such as inorganic conductive materials (e.g., metals), semiconductive materials and insulator materials. Suitable semiconductor materials include those disclosed in U.S. patent application Ser. No. 10/796,832 and include any type of semiconductor, including group II-VI, group III-V, group IV-VI and group IV semiconductors. Suitable semiconductor materials include, but are not limited to, Si, Ge, Sn, Se, Te, B, C (including diamond), P, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, (Al, Ga, In)₂ (S, Se, Te)₃, Al₂CO, and an appropriate combination of two or more such semiconductors. Suitable metals include, but are not limited to, Group 10 atoms such as Pd, Pt or Ni, as well as other metals, including but not limited to, W, Ru, Ta, Co, Mo, Ir, Re, Rh, Hf, Nb, Au, Ag, Fe, and Al. Suitable insulator materials include, but are not limited to, SiO₂, TiO₂ and Si₃N₄. In further embodiments, the masking nanoparticles for use in the practice of the present invention can be prepared from suitable polymers, for example, polystyrene, poly(methyl methacrylate), as well as other polymers known in the art.

The masking nanoparticles useful in the present invention can also further comprise ligands conjugated, associated, or otherwise attached to their surface as described throughout. Suitable ligands include any group known to those skilled in the art, including those disclosed in (and methods of attachment disclosed in) U.S. patent application Ser. No. 10/656,910, U.S. patent application Ser. No. 11/034,216, and U.S. Provisional Patent Application No. 60/578,236, the disclosures of each of which are hereby incorporated by reference herein for all purposes. Use of such ligands can enhance the ability of the masking nanoparticles to associate and spread on the various material surfaces that are being patterned, such that the material surface is substantially covered by masking nanoparticles in a uniform, ordered manner. In addition, such ligands act to keep the individual masking nanoparticles separate from each other so that they do not aggregate together prior to or during application.

Nanostructures produced by the methods of the present invention can be produced from any suitable material, including an inorganic material, such as inorganic conductive materials (e.g., metals), semiconductive materials and insulator materials. Suitable semiconductor materials include those disclosed in U.S. patent application Ser. No. 10/796,832 and include any type of semiconductor, including group II-VI, group III-V, group IV-VI and group IV semiconductors. Suitable semiconductor materials include, but are not limited to, Si, Ge, Sn, Se, Te, B, C (including diamond), P, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, (Al, Ga, In)₂ (S, Se, Te)₃, Al₂CO, and an appropriate combination of two or more such semiconductors. Suitable metals include, but are not limited Pd, Pt, Ni, W, Ru, Ta, Co, Mo, Ir, Re, Rh, Hf, Nb, Au, Ag, Fe, Al, WN₂ and TaN. Suitable insulator materials include, but are not limited to, SiO₂, TiO₂ and Si₃N₄.

In exemplary embodiments, the present invention provides methods of nanopatterning a substrate. As used herein, the term “nanopatterning” refers to the disposing of masking nanoparticles onto a substrate to form a “nanoparticle pattern mask” which is then used to generate “nanostructures” and “nanocavities” using the various methods described throughout. Masking nanoparticles can be disposed onto a substrate using any suitable method, and includes, for example, spin-coating, spray-coating, layering, spreading, depositing and other forms of disposing onto the substrate. A “nanoparticle pattern mask,” as used herein, refers to a plurality of masking nanoparticles (e.g., 2, 5, 10, 50, 100, 1000, etc.) that have been disposed onto a substrate so as to form a pattern of masking nanoparticles. The masking nanoparticles therefore cover at least a portion of a substrate onto which they have been disposed. Suitably, the masking nanoparticles are substantially uniform in size and substantially uniformly spaced on the substrate. As used herein, the phrase “substantially uniform in size” means that the diameters (cross-sectional diameter of the nanoparticles taken normal to the surface) of nanoparticles (including masking nanoparticles) have a standard distribution of less than about 30%, suitably less than about 25%, less than about 20%, less than about 15% or less than about 10%. As used herein, the phrase “substantially uniformly spaced” means that the center-to-center spacing between adjacent nanoparticles (including masking nanoparticles) varies by less than about 30%, suitably less than about 25%, less than about 20%, less than about 15%, or less than about 10%. Suitably, the masking nanoparticles are homogenously distributed across the surface of the substrate, though in additional embodiments, the masking nanoparticles can be selectively or specifically disposed in a particular area(s) of the substrate, or the distribution can be random across the surface of the substrate.

As discussed throughout, masking nanoparticles for use in the practice of the present invention can be prepared using any suitable process. In exemplary embodiments, the masking nanoparticles are prepared by processes disclosed in U.S. patent application Ser. No. 11/506,769, filed Aug. 18, 2006, the disclosure of which is incorporated by reference herein in its entirety.

For example, masking nanoparticles of the present invention can be prepared from Group 10 metal nanostructures, for example, Pd, Pt or Ni. As discussed throughout U.S. patent application Ser. No. 11/506,769 (the '769 application), a precursor comprising a Group 10 atom having an oxidation state of +2, and that is bonded to one or more oxygen atoms, is provided. The precursor is reacted in the presence of a surfactant and a non-coordinating solvent to produce the masking nanoparticles. Exemplary precursors include precursors in which the Group 10 atom is bonded to one or more carboxylate or beta diketone moieties (e.g., to an oxygen atom of the carboxylate or ketone moiety). For example, the Group 10 atom can be bonded to one or more acetate, butyrate, oxanilate, or acetylacetonate moieties (e.g., to two such moieties). Exemplary surfactants and non-coordinating solvents are described throughout the '769 application, and include, for example, phosphines, thiols, phosphine oxides (e.g., tri-n-alkyl phosphine oxides), sulfonates, amines (e.g., oleylamine), diols (e.g., propanediol), and carboxylic acids.

In further embodiments, the masking nanoparticles can be produced from ruthenium, using, for example, the methods discussed throughout the '769 application. In suitable methods, a precursor comprising a Ru atom (e.g., ruthenium (III) acetylacetonate, ruthenium chloride, or a ruthenocene) is provided and reacted, typically in the presence of an additive such as an oxidizing agent, a base, or a carboxylate (e.g., an acetate) to produce the nanoparticles. Exemplary additives include, but are not limited to, ammonium nitrate, nitric acid, a peroxide, hydrogen peroxide, ammonium acetate, tetramethylammonium acetate, ammonium hydroxide, and tetramethylammonium hydroxide.

As discussed throughout, suitably the masking nanoparticles have a standard deviation in diameter which is less than about 30% of an average diameter of the nanostructures. The standard deviation is suitably less than about 20% of the average diameter, less than about 15%, or less than 10% of the average diameter. The size distribution of the masking nanoparticles is preferably monomodal. The masking nanoparticles can be of essentially any size, but the average diameter is suitably less than about 20 mm, for example, between about 1-20 mm, or between about 1-15 mm, between about 1-10 nm, or between about 1-5 nm. For example, the masking nanoparticles can be about 20 nm in diameter, or about 19 nm, about 18 mm, about 17=n, about 16 mm, about 15 mm, about 14 nm, about 13 nm, about 12 nm, about 111 n, about 10 mm, about 9 mm, about 8 mm, about 7 mm, about 6 mm, about 5 mm, about 4 mm, about 3 nm, about 2 nm, or about 1 nm. The masking nanoparticles can be of essentially any shape, including spherical (or substantially spherical, e.g., oblong), rods, wires tetrapods or other shapes.

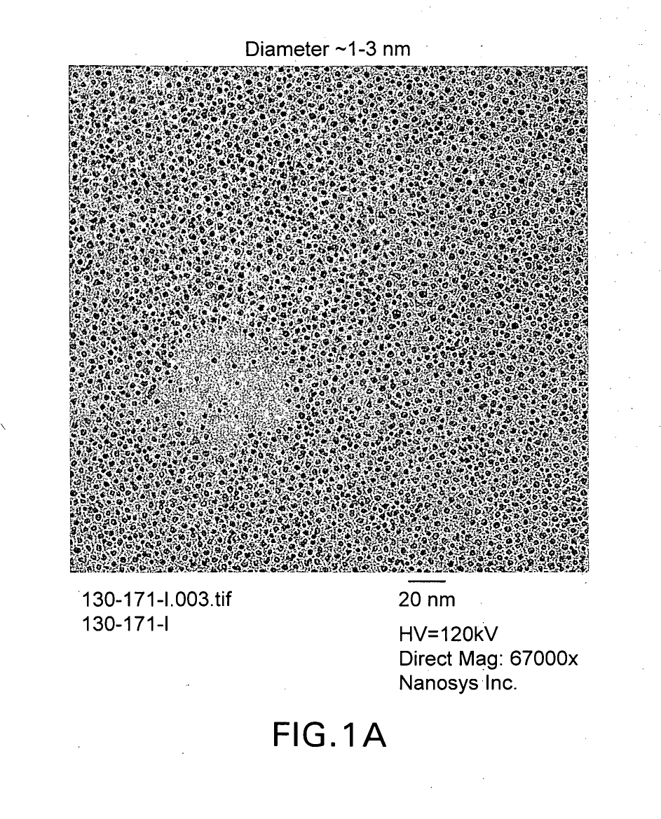

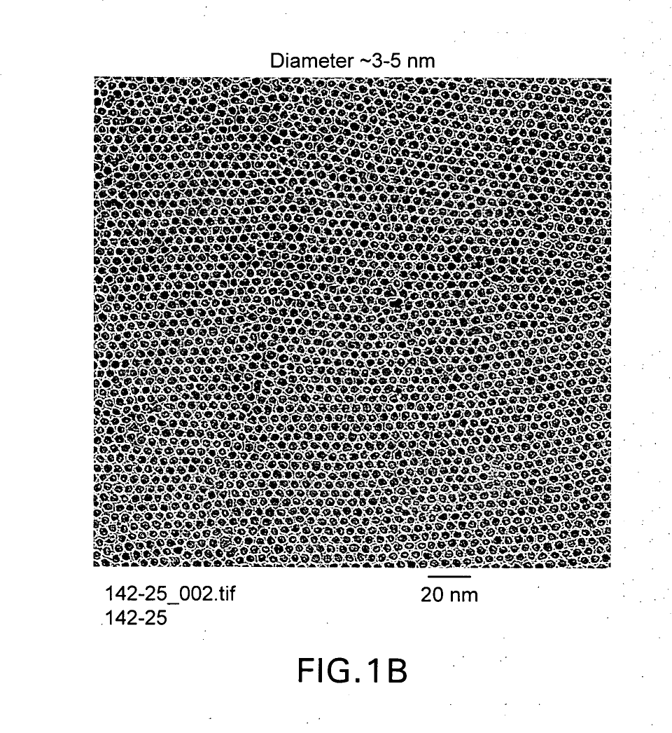

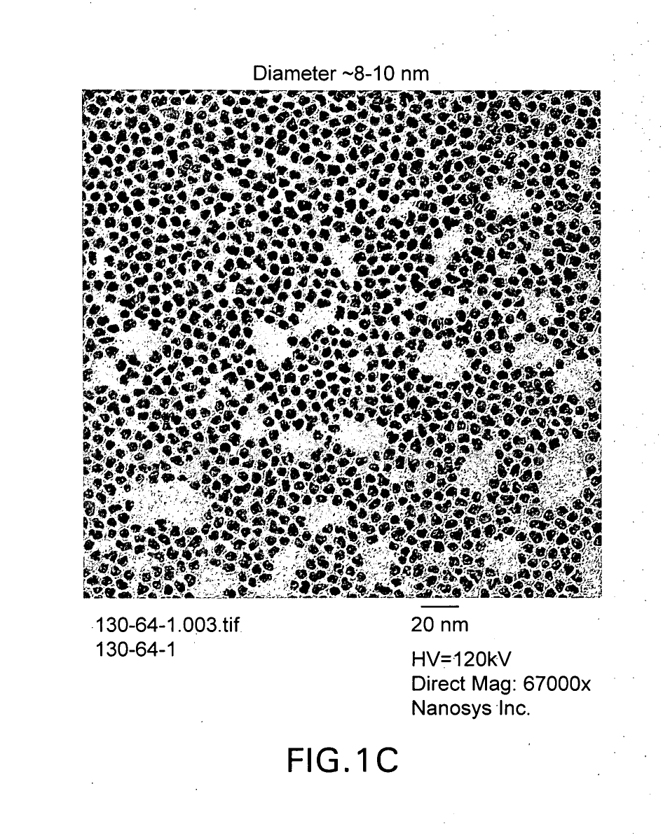

Through variations in incubation temperature, time and other factors, the size of the masking nanoparticles can be tightly controlled. For example, as shown in FIGS. 1A-1C, masking nanoparticles with diameters of about 1 nm to about 10 nm can be reproducibly prepared, with very little variability in their diameters. FIG. 1A shows a transmission electron micrograph (TEM) of ruthenium masking nanoparticles prepared in accordance with the methods described herein and in the '769 application. The diameter of the nanoparticles ranges from about 1 nm to about 3 nm, and as can be seen, the variability between the size of the particles is quite small. In preparation for the TEM, the nanoparticles were spin coated onto the substrate, resulting in a very evenly distributed coating of nanoparticles. As can be seen in FIG. 1A, the center-to-center distance between the nanoparticles is very uniform, generally on the order of about 3-5 nm.

FIG. 1B shows a TEM of masking nanoparticles of about 3-5 nm in diameter prepared in accordance with the present invention. FIG. 1B demonstrates the extremely small variation in nanoparticle diameter, as well as center-to-center spacing between adjacent nanoparticles. FIG. 1C shows an additional TEM of masking nanoparticles having a diameter of between about 8-10 nm. As in FIGS. 1A and 1B, the diameter of the nanoparticles is very uniform, as is the inter-nanoparticle spacing. The pattern of masking nanoparticles exhibits some additional heterogeneity, but overall the spin-coating method has produced a uniform pattern.

### Nanostructures and Nanocavities

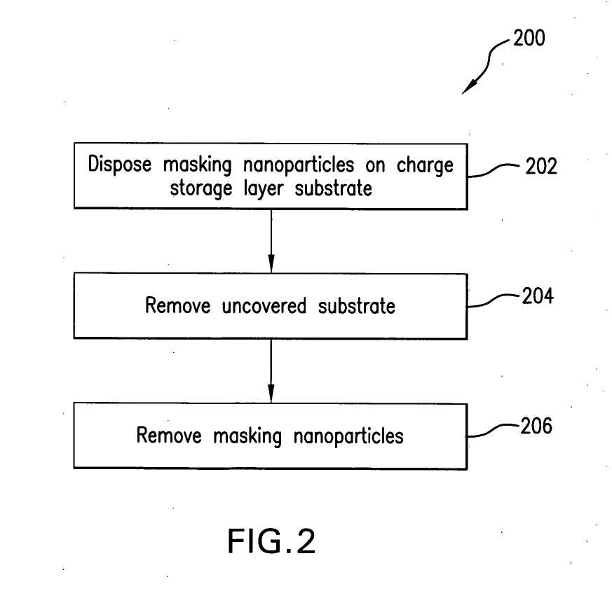

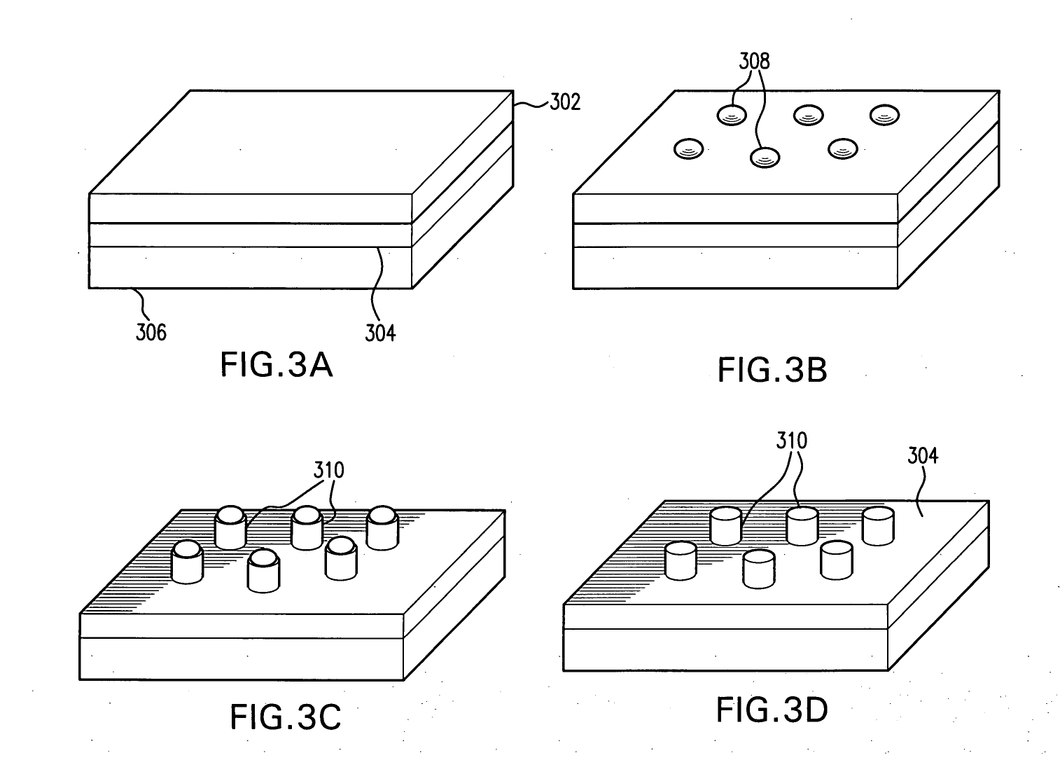

In one embodiment, as shown in flowchart 200 of FIG. 2, with reference to the schematic in FIGS. 3A-3D, the present invention provides methods for generating one or more nanostructures, as well as nanostructures prepared by such methods. In suitable embodiments, the methods are useful for preparing nanostructures of charge storage layers. In step 202 of FIG. 2 one or more masking nanoparticles 308 are disposed on a substrate 302, to at least cover a portion of the substrate (see FIG. 3B). Suitably, substrate material 302 is a charge storage layer substrate. Substrate 302 can be provided by itself, or it can be provided layered or otherwise associated with additional optional substrates. For example, as shown in FIG. 3A, substrate material 302 can be layered on optional insulating layer 304 which is itself layered on optional base substrate 306.

Any suitable substrate material can be utilized in the practice of the present invention, and hence, nanostructures of any suitable substrate can be produced using the methods described throughout. In exemplary embodiments, substrate 302 is a charge storage layer, for example, a layer comprising a metal, such as, but not limited to, W, WN₂, TaN and Iridium. In further embodiments, substrate 302 comprises a semiconductor material, e.g., Si, Ge, Sn, Se, Te, B, C, or an insulator material, e.g., SiO₂, TiO₂ and Si₃N₄.

Suitably, substrate material 302 is a metal charge storage layer, for example, a layer of W, WN₂, TaN or Iridium. In exemplary embodiments, substrate material 302 comprises a contiguous layer of metal that has been formed on an optional substrate layer, for example, an insulating substrate layer (304), such as SiO₂. Any method can be used to form substrate layer, for example, CVD/PVD can be used to deposit a layer of metal on, for example, a SiO₂ insulating layer (304) that itself has been deposited (e.g., grown or generated) on a base substrate (306) (e.g., a Si base substrate). The thickness of layers 302, 304 and 306 vary depending upon the type of substrate and optional substrate layers. Suitably, substrate material 302 (e.g., metal) is on the order of 1-50 nm thick, more suitably about 1-20 nm or about 1-10 nm, most suitably about 1-8 nm, e.g., about 2 nm, about 3 nm, about 4 nm, about 5 nm, about 6 mm, about 7 nm or about 8 nm thick. Optional insulting layer 304 (e.g., SiO₂) is suitably on the order of 10s-100s of nanometers in thickness, though thinner or thicker layers can also be utilized. Optional base substrate 306 (e.g., Si) is suitably on the order of 100s of nanometers thick, to several millimeters or larger, depending on the desired substrate and application.

As used herein and discussed throughout, methods for disposing masking nanoparticles 308 on substrate 302 include any suitable method known in the art, such as spin-coating and spray-coating. The term “disposing” as used herein is meant to encompass any of the terms known in the art such as formed, layered, attached, associated, generated, deposited, grown, bonded, etc., which indicate that the masking nanoparticles of the present invention are associated with a surface of the substrate 302. Methods for spin-coating nanoparticles onto substrates are known, for example, as disclosed in, U.S. patent application Ser. No. 10/674,060, filed Sep. 30, 2003, the disclosure of which is incorporated by reference herein in its entirety. As discussed throughout, masking nanoparticles can be prepared from any suitable material, including metals, semiconductors and polymers. Suitably, the masking nanoparticles are prepared from metals including, but not limited to, Pd, Ni, Ru, Co and Au. In exemplary embodiments, the diameter of the masking nanoparticles is between about 1 nm to about 20 nm, suitably about 1 nm to about 15 nm, or about 1 nm to about 10 nm, e.g., about 1 nm, about 2=n, about 3 nm, about 4 nm, about 5 nm, about 6 nm, about 7 nm, about 8 nm, about 9 nm or about 10 nm in diameter. As demonstrated in FIGS. 1A-1C, the diameter of the masking nanoparticles of the present invention can be controlled such that the masking nanoparticles are “substantially uniform in size,” i.e., such that the diameters vary by less than about 15%. Furthermore, as shown in FIGS. 1A-1C, masking nanoparticles 308 are disposed on substrate 302 in a uniform orientation or pattern, such that a substantial portion of substrate 302 is covered by masking nanoparticles, e.g., greater than about 50%, greater than about 60%, greater than about 70%, greater than about 80%, greater than about 90%, or greater than about 95% of substrate 302 is covered.

Masking nanoparticles provide a way to selectively cover portions of substrate 302, such that these covered portions are protected from external reactants (chemicals, light, plasma, heat, other energy/reaction sources). However, uncovered portions remain exposed to reactants in the surrounding environment. For example, as shown in step 204 of flowchart 200, when uncovered substrate is selectively removed from substrate 302, substrate nanostructures 310 remain at the site of the masking nanoparticles. Suitably, uncovered substrate is removed by etching substrate 302. However, since the portions of substrate 302 that are covered by masking nanoparticles 308 are protected from etching, only the unprotected portions of substrate 302 are removed. Therefore, as substrate 302 is selectively etched, nanostructures 310 are formed “below” the masking nanoparticles (e.g., FIG. 3C). It should be understood that the term “below” represents one embodiment of the present invention in which the spatial orientation of substrate 302 and masking nanoparticles 308 is as represented in FIGS. 3A-3D, and other spatial orientations are readily envisioned by one of ordinary skill in the art and therefore fall within the scope of the present invention. It should also be understood that the number and orientation/spacing of masking nanoparticles 308 in FIGS. 3A-3D is provided only for illustrative purposes. In exemplary embodiments, masking nanoparticles 308 are disposed in closer proximity and over a wider range on substrate 302 than is illustrate in FIGS. 3A-3D.

As used herein, the terms “etch” or “etching” refer to any process, including chemical, physical, or energetic, which removes exposed or uncovered material of a substrate. Examples of suitable etching methods include, but are not limited to, chemical etching, such as acid or base etching, including wet chemical etches (e.g., using Acetic Acid (H₃COOH), Hydrochloric Acid (HCl), Hydrofluoric Acid (HF), Nitric Acid (HNO₃), Phosphoric Acid (H₃PO₄), Potassium Hydroxide (KOH), Sodium Hydroxide (NaOH), Sulfuric Acid (H₂SO₄), as well as other chemicals known by one of ordinary skill in the art, see e.g., U.S. Pat. Nos. 7,153,782, 7,115,526, 5,820,689); photochemical etching, see e.g., U.S. Pat. Nos. 4,414,066 and 5,092,957, as well as Ashby, “Photochemical Dry Etching of GaAs”, Appl. Phys. Lett. 45:892 (1984); Ashby et al., “Composition-selective Photochemical Etching of Compound Semiconductors”, Appl. Phys. Lett. 47:62 (1985), Smith, R. A., Semiconductors, 2nd Ed., Cambridge Univ. Press, New York, 1978, p. 279; plasma etching, see e.g., U.S. Pat. Nos. 3,615,956, 4,057,460, 4,464,223 and 4,595,454; reactive ion etching (RIE) see e.g., U.S. Pat. Nos. 3,994,793, 4,523,976 and 4,599,136; electron beam etching, see e.g., U.S. Pat. Nos. 4,639,301, 5,149,974 and 6,753,538, and also, Matsui et al., “Electron Beam Induced Selective Etching and Deposition Technology,” Journal of Vacuum Science and Technology B 7 (1989), Winkler et al. “E-Beam Probe Station With Integrated Tool For Electron Beam Induced Etching,” Microelectronic Engineering 31:141-147 (1996). Each of the patents and references listed above are hereby incorporated by reference herein in their entireties for all purposes, specifically for their disclosure of various etching methods and compositions. As represented in FIGS. 3A-D, substrate 302 is preferentially/selectively removed (e.g., preferentially/selectively etched), such that substrate material 302 is removed, but masking nanoparticles 308 are not removed/etched. Preferential removal/etching in accordance with the present invention requires selection of enchants that etch substrate 302, but not masking nanoparticles 308 (it should be understood that some etching of substrate is acceptable in the practice of the present invention). In embodiments where both substrate 302 and masking nanoparticles 308 comprise metal, careful selection of etchant(s) is required so that only substrate 302 is substantially etched. Such selectivity is readily determined by those of ordinary skill in the art, as described throughout the references noted above.

In exemplary embodiments, uncovered portions of substrate 302 are removed by etching anisotropically. As used herein, etching anisotropically means that the rate of etching in one primary direction is greater than the rate of etching in other directions. Suitably, in anisotropic etching, the rate of etching is nearly zero in directions other than the primary direction (for example, normal to the plane of the substrate surface). In further embodiments, the etching of substrate 302 can occur isotropically. Isotropic etching refers to an etching process in which the rate of etching is the same, or substantially the same, in all directions. That is, there is no primary direction of etching. For use in the practice of the present invention, while either anisotropic or isotropic etching can be used, anisotropic etching provides a method for controlling the amount, orientation and type of substrate that is being etched.

For example, as shown in FIG. 3C, the use of an anisotropic etch (e.g., RIE or electron beam etching) allows for substrate 302 that is not covered by masking nanoparticles to be etched away, but only in a direction that is normal to the plane of the substrate, thereby forming nanostructures below the masking nanoparticles 308. As the substrate is etched away anisotropically, i.e., only in a direction normal to the plane of the substrate, the cross-sectional diameter of the nanostructures that are generated are substantially the same size as the masking nanoparticles that covered the substrate. For example, if masking nanoparticles with a diameter of about 4 nm are disposed on a substrate and an anisotropic etched is performed on uncovered portions of the substrate such that the etching proceeds to a depth of about 4 nm, nanostructures with dimensions on the order of about 4×4 nm are generated. In further embodiments, the anisotropic etch can be performed for a longer or shorter time, so that nanostructures are formed that have one dimension longer than the other. For example, nanostructures with a cross-sectional diameter equal to about the diameter of the masking nanoparticles, but an extended length dimension can be generated. Or, disk-like nanostructures can be generated in which the cross-sectional diameter dictated by the size of the nanostructures is the larger dimension, and the “height” of the discs, the shorter dimension.

In further embodiments, the removing that takes place in step 204 of FIG. 2 can comprise an isotropic etch, such that substrate 302 that is both uncovered, and covered by masking nanoparticles 308 is etched at substantially the same rate. Nanostructures produced according to this embodiment have an initial cross-sectional diameter dictated by the size of the masking nanoparticles. However, as the isotropic etch removes substrate 302 both normal to the plane of the substrate, and substrate that is beneath the masking nanoparticles, the diameter of the nanostructure narrows as you move into the substrate. For example, a conical or hemispherical shape can be generated. As noted above, the size of the nanostructures generated using the methods of the present invention is controlled not only by the cross-sectional diameter of the masking nanoparticle, but also the depth that the etch removes material into the plane of the substrate.

As shown in step 206 of FIG. 2, masking nanoparticles 308 are then removed from substrate 302 and generated nanostructures 310, leaving nanostructures 310, as in FIG. 3D. Any suitable method can be used to remove masking nanoparticles, for example, simply washing or rinsing substrate 302 with a solution (e.g., alcohol or aqueous solution) to remove the masking nanoparticles. In other embodiments, the masking nanoparticles can be selectively etched away using the various methods known in the art and discussed throughout, or they can be melted away, or simply physically removed.

As shown in FIG. 3D, if an optional insulating layer 304 is disposed beneath substrate 302, the methods of the present invention allow for generation of nanostructures using various etching methods such that nanostructures 310 are positioned directly on the insulating layer 304, and hence, separated from one another by an insulating material 304. In suitable embodiments, the thickness of substrate 302 is such that removing (e.g., etching) in step 204 of FIG. 2 removes all uncovered substrate, and may even remove some portion of an underlying optional insulating layer 304. This allows for the generation of separated, individual nanostructures 310 that are not electrically connected.

As discussed above, and throughout U.S. application Ser. No. 11/641,956, filed Dec. 20, 2006 (the disclosure of which is incorporated herein by reference in its entirety), nanostructures prepared in accordance with the methods of the present invention can suitably be used in charge storage layers or charge storage media. For example, any nanostructures, including metal or semiconductor or dielectric nanostructures can be used, including ruthenium (Ru) nanostructures, suitably having a diameter of less than about 5 nm.

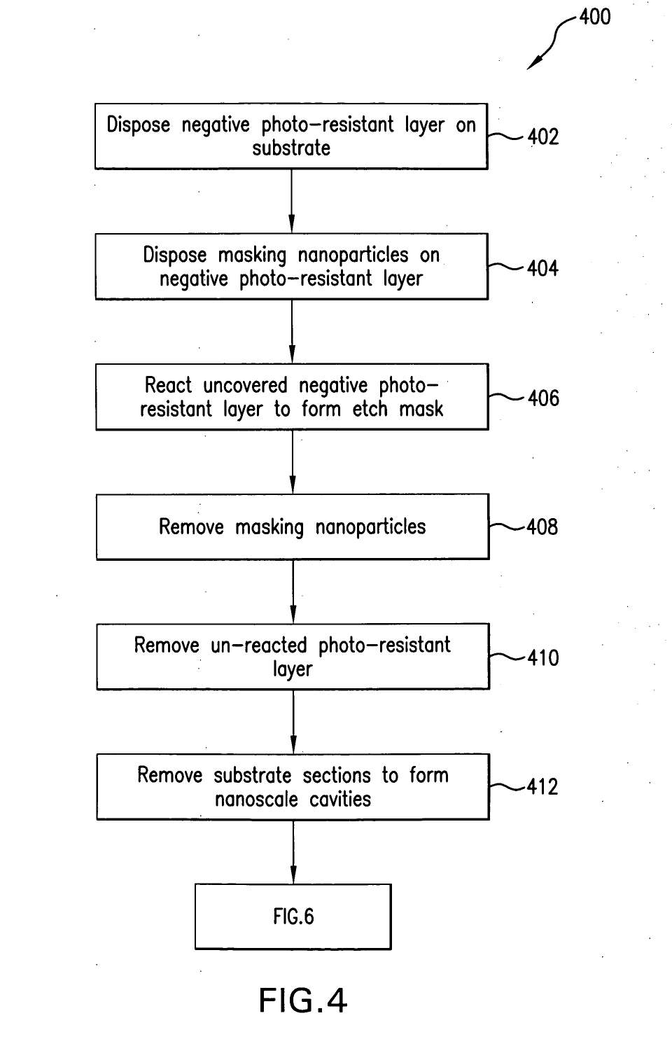

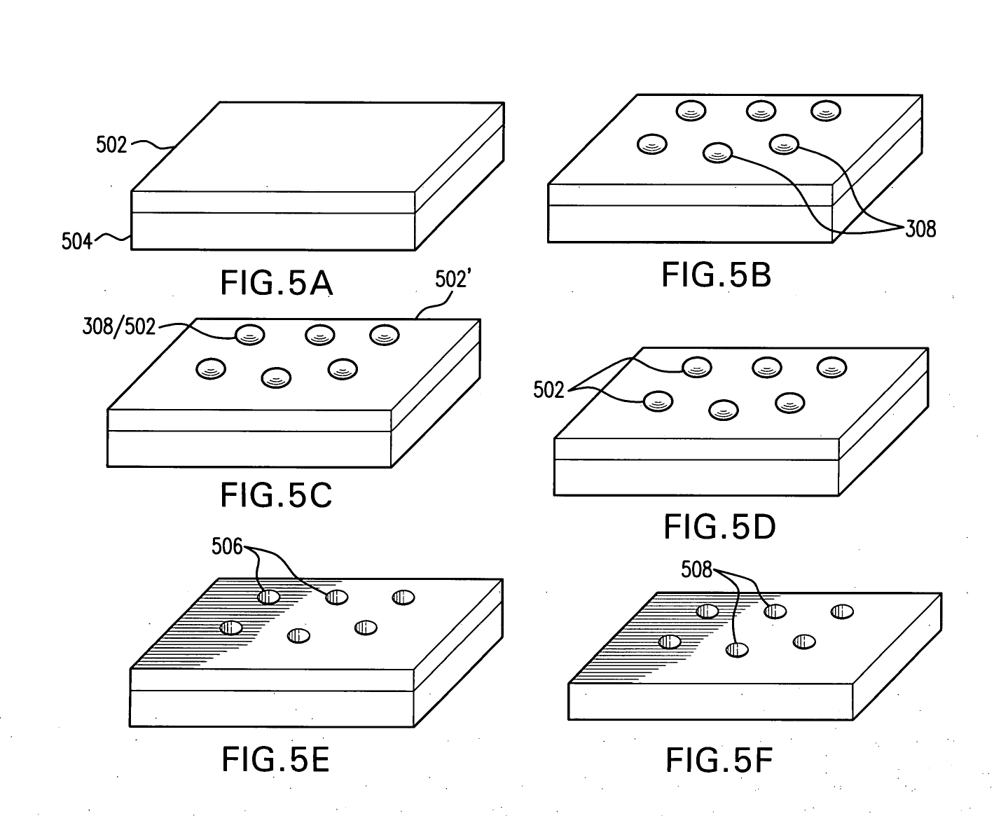

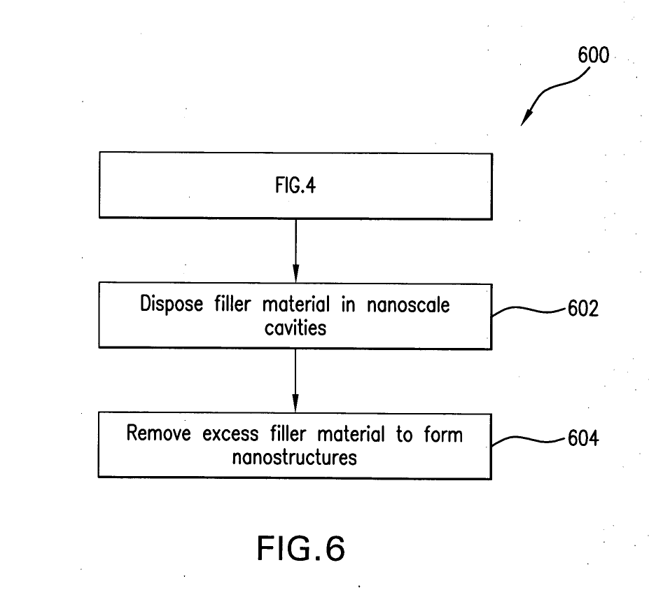

In additional embodiments, the present invention provides methods of generating nanoscale cavities in substrate materials, as shown in flowchart 400 of FIG. 4, with reference to FIGS. 5A-5F, as well as nanoscale cavities produced by such methods. As shown in FIG. 4, in step 402, a negative photoresistant layer 502 (or negative photoresist) is disposed on a surface of substrate 504 (FIG. 5A). Any suitable material can be used as substrate 504, though in exemplary embodiments, substrate 504 is an electrically insulating substrate, for example an oxide such as SiO₂. As used herein, a “negative photoresistant layer” refers to a material that, when exposed to radiation (including visible and ultraviolet light wavelengths, as well as electron beam and x-ray radiation) becomes relatively insoluble to a photoresist developer. Unexposed portions (i.e., covered) of the negative photoresistant layer are then able to be dissolved by a photoresist developer, while covered regions are not able to be developed. Examples of methods of the use of a negative photoresist layer, as well as photoresist developers, can be found in, for example, Sze, S. M., “Semiconductor Devices, Physics and Technology,” John Wiley & Sons, New York, pp. 436-442 (1985) the disclosure of which is incorporated by reference herein in its entirety. In general, negative photoresists for use in the practice of the present invention comprise a polymer combined with a photosensitive compound. Upon exposure to radiation (e.g., UV light), the photosensitive compound cross-links the polymer, rendering it resistant to a developing solvent. Unexposed areas, however, are removable by the developing solvent. Some exemplary negative photoresist materials and developers include Kodak® 747, copolymer-ethyl acrylate and glycidylmethacrylate (COP), GeSe and poly(glycidyl methacrylate-co-ethyl acrylate) DCOPA. Disposing of negative photoresist layers 502 can be performed using any suitable method, for example, spin coating, spray coating, or otherwise layering the layer.

In step 404 of flowchart 400 of FIG. 4, one or more masking nanoparticles 308 are then disposed on a surface of the negative photoresist layer 502 opposite the substrate 504 to cover at least a portion of the negative photoresist layer 502, as shown in FIG. 5B. Masking nanoparticles 308 can be disposed onto the negative photoresist layer 502 using any suitable method, for example, spin coating, spraying, or otherwise layering the nanoparticles. Exemplary materials, sizes and shapes of masking nanoparticles 308 are discussed throughout. It should also be understood that the number and orientation/spacing of masking nanoparticles 308 as shown in FIG. 5B is provided only for illustrative purposes. In exemplary embodiments, masking nanoparticles 308 are disposed in closer proximity and over a wider range on negative photoresist layer 502 than is illustrate in FIGS. 5A-5F.

In step 406 of FIG. 4, uncovered portions of negative photoresist layer 502 are reacted to form an etch mask. As noted above, various forms of radiation can be used to react the negative photoresist, including ultraviolet light. Reacting negative photoresist 502 converts the photoresist to a material that is resistant to removal by a developer, thereby forming an etch mask comprising one or more portions of a reacted negative photoresist 502′ and one or more portions of unreacted negative photoresist covered by masking nanoparticles 308/502, as shown in FIG. 5C. Removal of masking nanoparticles 308 in step 408 of FIG. 4 reveals the one or more portions of unreacted negative photoresist 502 that were originally covered by masking nanoparticles 308, as shown in FIG. 5D. Any suitable method can be used to remove masking nanoparticles 308, for example, simply rinsing substrate 502/502′ with a solution, e.g., an alcohol or aqueous-based solution.

In step 410 of flowchart 400 of FIG. 4, unreacted portions of negative photoresist 502 are removed, suitably by reacting the portions with a developing solvent. As shown in FIG. 5E, removal of these portion reveals one or more exposed substrate sections 506 of substrate 504. Substrate 504 still covered by reacted negative photoresist 502′ is protected from any subsequent removal process (e.g., etching). Thus, the methods of the present invention provide a means for producing a negative photoresist layer that has nanopatterned openings or portions throughout.

In step 412 of FIG. 4, exposed substrate sections 506 are then removed. For example, substrate sections 506 are removed normal to the surface of the substrate, thereby forming one or more nanoscale cavities 508 at the site of the exposed sections, as shown in FIG. 5F. Suitably, substrate sections are removed by etching, including anisotropically etching via RIE or electron beam etching, as described throughout. While the methods of the present invention directed to forming nanoscale cavities can be performed on any suitable substrate, in exemplary embodiments, the nanoscale cavities are formed in an electrically insulating substrate, such as SiO₂.

The cross-sectional diameter of nanoscale cavities 508 is dictated by the diameter of masking nanoparticles 308, and hence, as discussed throughout, nanoscale cavities on the order of between about 1-20 nm in diameter, suitably about 1-10 nm in diameter, or about 1-5 nm in diameter are readily prepared. The depth of nanoscale cavities 508 is controlled by the extent of removal of substrate 504 in step 412. Thus, by controlling the time of removal (etch), and the removal (etch) rate (e.g., via varying the type of etch and intensity), the depth of nanoscale cavities can be controlled to any desired depth. Suitably, the depth of removal (etch) is similar to the diameter of the masking nanoparticles/nanoscale cavities, i.e., between about 1-20 nm, though deeper cavities can be prepared depending on the desired final application.

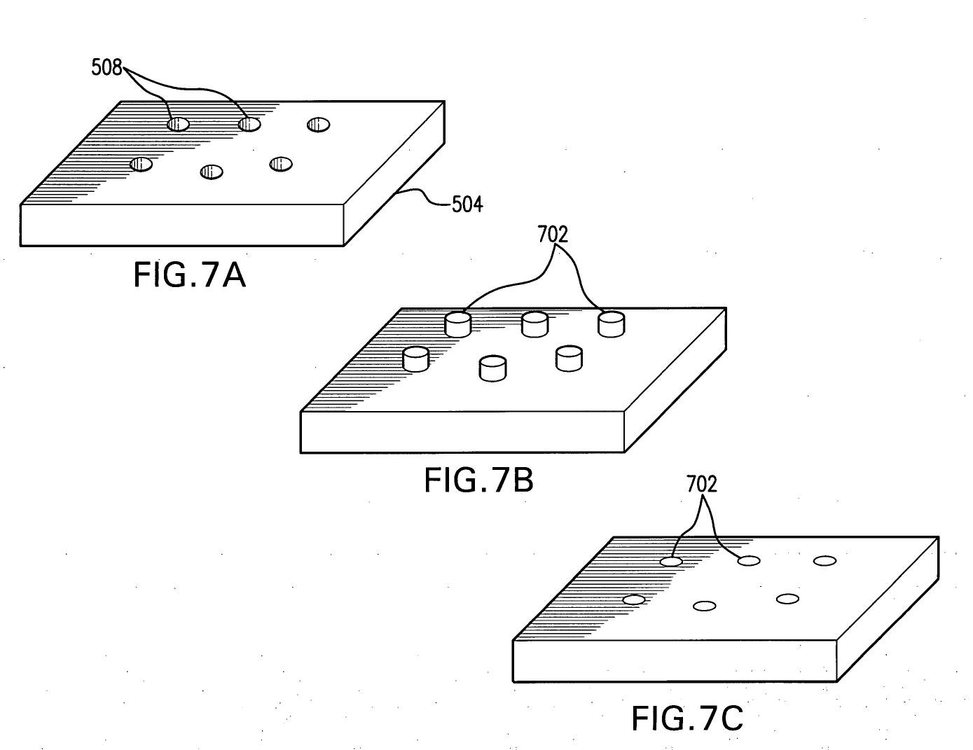

Substrates comprising nanoscale cavities prepared in accordance with the present invention can be used to create nanostructures, as shown in flowchart 600 of FIG. 6, with reference to FIGS. 7A-7C. For example, as shown in flowchart 600 of FIG. 6, upon providing a substrate material 504 with nanoscale cavities 508 (e.g., the product of FIG. 4, FIG. 7A), a filler material 702 can then be disposed in the nanoscale cavities 508 in step 602 of FIG. 6, as shown in FIG. 7B. Any suitable method for disposing filler material 702 into nanoscale cavities can be used, for example, chemical vapor deposition, physical vapor deposition, evaporation, etc.

In general, filler material 702 is a conductive material, such as a metal, including those described throughout. In other embodiments, filler material 702 can comprise a semiconductor material, such as polysilicon. The ability to prepare nanoscale cavities 508 that have a defined size (dictated by the diameter of masking nanoparticles 308 and the depth of removal/etch), allows for the preparation of nanostructures by simply filling the cavities with a filler material. As shown in step 604 of FIG. 6, excess filler material 702 can then optionally be removed, thereby resulting in nanostructures that are of a defined size. For example, by etching filler material 702, excess material is removed down to the level (or below) of the surface of substrate 504. Suitable etching methods, including RIE and electron beam etching are described throughout. Removal in step 604 can comprise anisotropic or isotropic etching, thereby removing filler material in all orientations, or in a preferred orientation, e.g., into the plane of substrate 504. In additional embodiments, heating can be used to locate filler material 702 to the sites of the nanoscale cavities 508. For example, filler material 702 can be heated to a temperature above its melting temperature such that it flows into nanoscale cavities, and thus is removed, or substantially removed, from the surface of substrate 504.

Filler material 702 thereby forms nanostructures throughout substrate 504, each separated from one other by substrate 504. In suitable embodiments, filler material comprises a metal (e.g., W, WN₂, TaN or Iridium), and nanostructures of these metals can be separated by substrate 504, which can be an insulator such as SiO₂. As SiO₂ has a higher barrier height than other dielectrics, including high-k, it is therefore very effective in suppressing lateral charge diffusion between nanostructures (e.g. metal nanostructures). Thus, these nanostructures and substrates can be used as charge storage layers as described throughout. In embodiments in which nanocavities are generated in SiO₂, and then a metal filler material is used to generate nanostructures in the dielectric, such embodiments allow for the production of layers comprising very high nanosructructure density with fairly thin sections of SiO₂ between nanostructures.

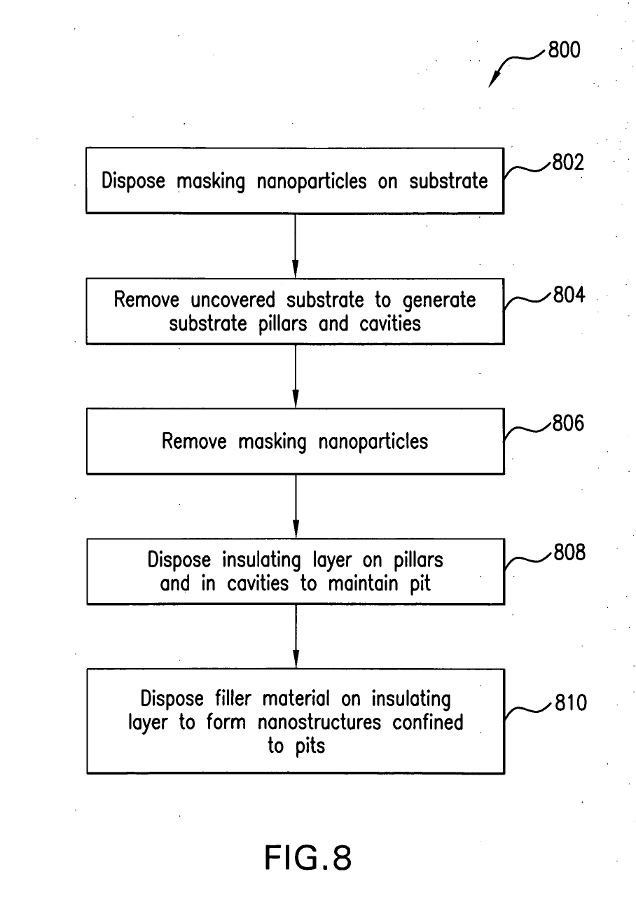

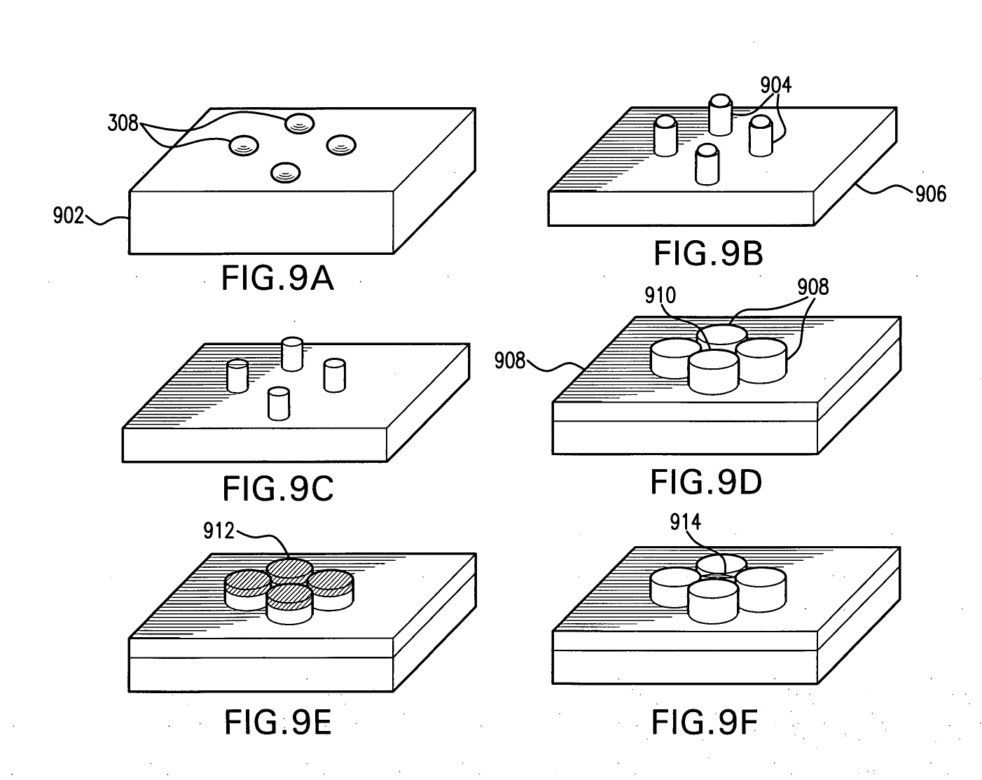

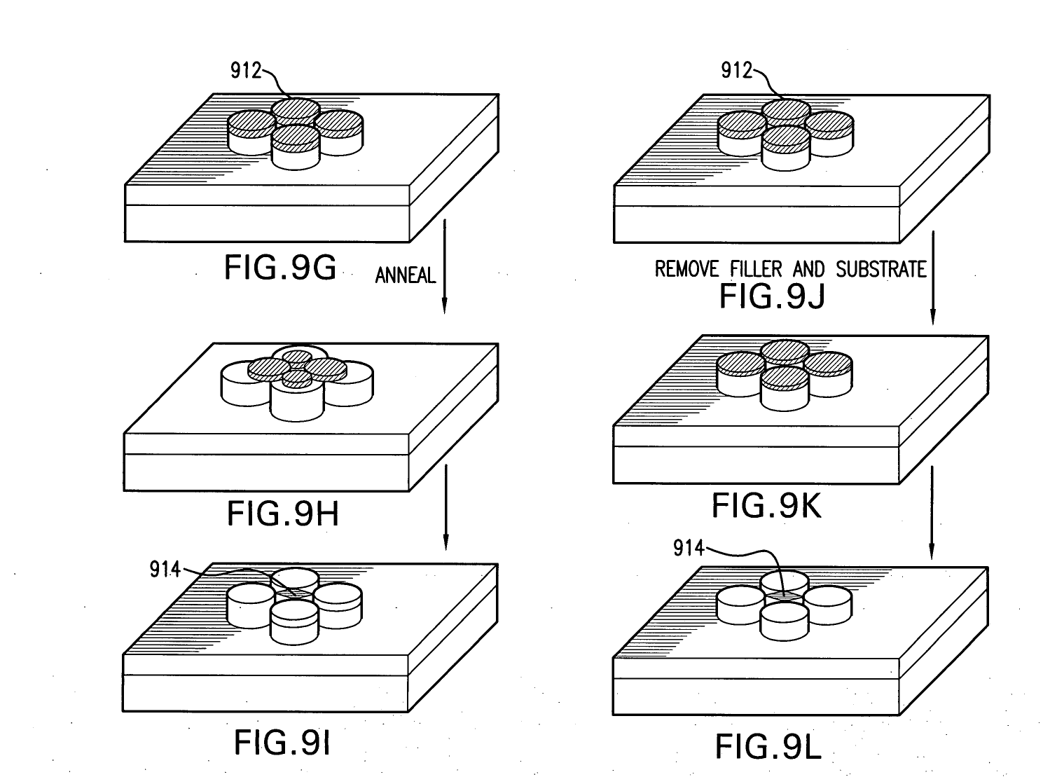

Further methods are provided for generating one or more nanostructures of a filler material, as shown in flowchart 800 in FIG. 8 with reference to FIGS. 9A-9L, as well as nanostructures prepared by such methods. In step 802 of FIG. 8, one or more masking nanoparticles 308 are disposed on a surface of substrate 902 to a least cover a portion of the substrate. Suitably, substrate 902 is a semiconductor material, for example, Si, Ge, Sn, Se, Te, B or C. Exemplary materials, sizes and shapes of masking nanoparticles 308 are described throughout, as are methods for disposing masking nanoparticles on a surface of substrate 902. Suitably masking nanoparticles 308 are between about 1-10 nm, suitably about 1-5 nm in diameter, and comprise a metal such as Pd, Ni, Ru, Co or Au. The ability to provide a uniform disposition of masking nanoparticles 308 on substrate 902, allows for a very tightly controlled center-to-center spacing. For example, as shown in FIGS. 1A-1C, the center-to-center spacing can be controlled to within about 15%, with a separation distance of about 1-10 nm, suitably about 3-8 nm. It should also be understood that the number and orientation/spacing of masking nanoparticles 308 in FIGS. 9A-9L is provided only for illustrative purposes. In exemplary embodiments, masking nanoparticles 308 are disposed in closer proximity and over a wider area on substrate 902 than is illustrated in FIGS. 9A-9L.

In step 804 of FIG. 8, uncovered substrate material 902 is removed, suitably normal to the substrate surface, thereby forming substrate pillars 904 at the portion of the substrate covered by masking nanoparticles 308. As shown in FIG. 9B, substrate cavities 906 are also formed between substrate pillars 904 at portions of substrate 902 that were not covered by masking nanoparticles 308. Step 804 is similar to step 204 of FIG. 2, in which nanostructures of a substrate were generated by selectively removing material that was not covered by masking nanoparticles 308. Step 804 also results in the generation of nanostructures with a cross-sectional diameter that is about the same as the diameter of masking nanoparticles 308. While the “depth” or “height” of substrate pillars 904 may be larger than the nanostructures prepared in step 206, the process of preparation is very similar. As noted above, exemplary methods for selectively removing substrate material that can be used in step 804 include various etching methods, including RIE and electron beam etching. Suitably the etching is anisotropic etching so as to form substrate pillars 904 that have substantially uniform diameters throughout their length. In step 806 of FIG. 8, masking nanoparticles 308 are removed as shown in FIG. 9C, for example, by rinsing the substrate with a solution, e.g., an alcohol or aqueous-based solution.

In step 808 of FIG. 8, an insulating layer 908 is then disposed on the pillars 904 and cavities 906, so that a pit 910 is maintained at the site of the cavities, as shown in FIG. 9D. Suitably, insulating layer 908 is disposed on substrate 902 by growing an oxide layer. For example, if substrate 902 comprises Si, and oxygen is provided to the substrate, a layer of SiO₂ grows on the substrate pillars 904 and cavities 906. As insulating layer 908 is disposed, e.g., grown, on substrate pillars 904 and cavities 906, the layer “grows” equally in all directions from/on the substrate. That is, the layer increases in thickness in a direction normal to the substrate surface 902 on both the cavities 906 and pillars 904, as well as in directions that are parallel to the substrate surface 902, e.g., in directions normal (or substantially normal) to the sides of pillars 904. As used throughout, the term “grows,” as used to describe the disposition of insulating layer 908 is used to indicate that the insulating layer is formed, applied, deposited or otherwise generated on substrate 902, substrate pillars 904 and cavities 906, and is not to be limited to actual growth of the insulating layer (e.g., an oxide layer). For example, as shown in FIG. 9D, insulating layer 908 grows in all directions from substrate 902, including normal to the surface of substrate 902 and substrate cavities 906, as well as from the top and sides of substrate pillars 904.

The amount of insulating layer 908 that is disposed on the substrate surfaces can be controlled in various ways, depending on the method of disposition. For example, by removing or increasing the amount of oxygen, the thickness of a growing oxide layer can be controlled. By controlling the amount of insulating layer disposed on the various substrate surfaces, a pit 910 is maintained at the site of cavities 906. As insulating layer 908 is disposed equally on all surfaces of substrate 902, pit 910 is therefore lined (i.e., bottom and sides of the pit) with the insulating material, as shown in FIG. 9D. Pits 910 can be formed in any shape, but suitably they are in a hemisphere or conical shape. In suitable embodiments, as insulating layer 908 is disposed on substrate 902, the layer increases in thickness from the sides of substrate pillars 904 as well as from the cavities 906 in such a way that inverted cone or pyramid shape is generated. In addition to controlling the shape of pits 910, the size of pit 910 is very tightly controlled by providing a uniform disposition of masking nanoparticles 308 as discussed above. For example, as shown in FIGS. 1A-1C, center-center spacings, and hence, the size of cavities 906, can be controlled to within about 15%, with a separation of about 1-20 nm, suitably about 1-10 nm. Thus, pits 910 formed at the site of cavities 906 can also be controlled in this range, thereby forming pits with sizes of less than about 20 nm, suitably less than about 10 nm, or less than about 5 nm.

In step 810 of FIG. 8, a filler material 912 is disposed on the insulating layer 908, wherein the filler material is confined to pits 910. As shown in FIGS. 9E and 9F, in suitable embodiments, filler material 912 is disposed on insulating layer that forms the surface of pits 910, as well as insulating layer 908 that is outside of pits 910. As discussed throughout, filler material can comprise various materials, including semiconductor and conductor materials, such as metals and polysilicon. Exemplary methods for disposing filler material 912 are also discussed throughout, and include, for example, chemical vapor deposition, physical vapor deposition and evaporation.

While in exemplary embodiments, filler material is disposed only at the sites of pits 910, hence, confining the filler material to these locations, in other embodiments, filler material 912 is disposed on all surfaces of insulating material 908. Thus, in order to generate distinct, separate nanostructures of filler material 914, it may be necessary to perform additional processing to confine filler material 912 to pits 910 during the formation of nanostructures of filler material 914.

One exemplary method for confining filler material 912 to pits 910, is to anneal filler material 912, as shown in FIGS. 9G-9I. By heating filler material 912 to a temperature greater than the filler material annealing temperature (e.g., for at least 2 minutes, at least 5 minutes, at least 10 minutes, or at least 20 minutes), filler material 912 is able to migrate into (e.g., flow), and be confined to, pits 910. As shown in FIG. 9G (same view as FIG. 9E following deposition of filler material 912), filler material 912 initially present both in pits 910, and on insulating material 908 on pillars 904, migrates into pits 910 in FIG. 9H as the filler material is annealed, and then is ultimately confined to pits 910, thereby forming individual, distinct, separate nanostructures of filler material 914, separated by insulator material 908, as shown in FIG. 9I.

In further embodiments, disposing step 810 can comprise depositing a filler material onto insulator layer 908, followed by subsequently removing a portion of filler material 912 and a portion of insulator material 908, as shown in FIGS. 9J-9L. Filler material 912 can also be annealed following depositing of the material, but prior to removal of a portion of the material. Filler material can be deposited using any of the exemplary methods described throughout or otherwise known in the art, for example, by chemical vapor deposition, physical vapor deposition or evaporation.

As discussed above, it is desirable to produce individual, separate, distinct nanostructures of filler material 914 separated by insulator material 908. Following depositing of filler material 912 (FIG. J, same as FIG. 9E), a portion of the filler material, as well as a portion of insulator layer can be removed, as shown in FIG. 9K. For example, filler material 912 and insulator material 908 can be removed by mechanical polishing or by etching, including isotropic and anisotropic etching, for example, using RIE or electron beam etching. Suitably, at least all of filler material 912 above or on top of substrate pillars 904 is removed (e.g., etched), while at least some of the filler material 912 in pits 910 is not removed (e.g., etched). Thus, as shown in FIGS. 9K-9L, filler material 912 that was deposited on top of substrate pillars 904 is suitably etched such that all of this material is removed. Further removal, e.g., etching, into the surface of insulator material 908 that was grown on substrate pillars 904, while removing some of filler material 912 present in pits 910, forms individual, separated filler material nanostructures 914 surrounded by insulator material 908, as shown in FIG. 9L.

As discussed above, the ability to tightly control the center-to-center distance between adjacent masking nanoparticles provides the ability to prepare pits that are between about 1-10 nm in size, or about 1-5 nm in size. Thus, filler material nanostructures 914 generated by filling in pits 910 with filler material 912 are also prepared in this size range, e.g., between about 1-10 nm in diameter, or between about 1-5 nm in diameter. Furthermore, as noted above, the shape of pit 910 is suitably that of an inverted cone or pyramid. Thus, filler material nanostructures 914 also assume this shape. This provides a method then to prepare nanostructures with sizes of between about 1-20 nm, or about 1-10 nm, or even about 1-5 nm, with a pointed tip or surface directed into a layer of insulating material (908). As discussed below, such structures provide very unique properties useful in charge storage layers, and similar applications.

### Charge Storage Layers and Field Effect Transistors

The present invention also provides methods for preparing charge storage materials (e.g., layers) comprising metallic nanostructures, as well as charge storage materials comprising metallic nanostructures prepared by such methods. As discussed herein, the various methods of the present invention are useful for preparation of nanostructures, including metallic nanostructures, in the size range of about 1-20 nm. The ability to control the size and spacing of masking nanoparticles 308 translates directly to very uniformly sized and spaced product nanostructures. As discussed throughout U.S. application Ser. No. 11/641,956, the disclosure of which is incorporated by reference herein in its entirety, nanostructures, including metal, semiconductor or dielectric nanoparticles, are useful in charge storage materials. For example, charge storage layers suitably comprise nanocrystals formed of a high work function (e.g., greater than 4.5 eV) metal such as ruthenium (Ru), and suitably have a size of less than about 5 nm.

As discussed herein, nanostructures according to the present invention are suitably prepared directly either on top of an insulating layer, or such that they are separated by an insulating layer, for example SiO₂. Charge storage materials prepared in accordance with the present invention can also include metal, semiconductor or dielectric nanostructures (e.g., nanoparticles, quantum dots or nanocrystals) prepared directly on a tunneling dielectric layer. Charge storage materials can also include a contiguous metal or semiconductor conductive layer, a non-contiguous metal or semiconductor conductive layer, a nonconductive nitride-based or other types of insulating charge trapping layer, a nonconductive oxide layer (e.g., SiO₂) having conductive nanostructures prepared thereon, in accordance with the methods described throughout. For further description of charge storage layers that include nitrides, refer to U.S. Pat. No. 5,768,192, which is incorporated by reference herein in its entirety.

As discussed throughout U.S. patent application Ser. No. 11/641,956, because nanostructures (e.g., nanoparticles) of a charge storage layer separately store charge, and are insulated from one another, even if a single nanoparticle loses charge, this will not likely affect the remaining nanoparticles of the charge storage layer. Thus, a memory device incorporating such a charge storage layer is more likely to maintain a constant programmed state, over a much longer time than conventional memory devices.

One advantage of using the nanostructures of the present invention for charge a storage layer is that they do not form a continuous film, and thus charge storages formed of such nanostructures are self-isolating. Because nanostructures form a non-continuous film, charge storage layers can be formed without worrying about shorting of the charge storage medium of one cell level to the charge storage medium of adjacent cells lying directly above or below (i.e., vertically adjacent). Yet another advantage of the use of nanostructures of the present invention for charge storage layers is that they experience less charge leakage than do continuous film charge storage layers.

Nanostructures for use in the charge storage layers of the present invention can be formed from any suitable conductive material such as, but not limited to, palladium (Pd), iridium (Ir), nickel (Ni), platinum (Pt), gold (Au), ruthenium (Ru), cobalt (Co), tungsten (W), tellurium (Te), rhenium (Re), molybdenum (Mo), iron platinum alloy (FePt), tantalum nitride (TaN), etc. Such materials generally have a higher work function (e.g., about 4.5 eV or higher) than many semiconductors such as silicon, which is desirable for multiple electron storage, have a higher melting point (which allows a higher thermal budget), have longer retention times, and have high density of states for both positive and negative charge storage.

In further embodiments, the present invention provides a plurality metallic nanostructures (e.g., nanoparticles) having specified characteristics. For example, in suitable embodiments, the nanostructures comprise diameters between about 1 nanometer and about 10 nanometers, with size distributions no greater than about 15% of a mean diameter of the nanostructures. In further embodiments, the plurality of nanostructures comprise center-to-center spacings between adjacent nanostructures that are between about 1 nanometer and about 10 nanometers, where the center-to-center spacing is controlled to comprise a variance of about 10%. As discussed throughout, the masking nanoparticles of the present invention comprise highly uniform diameters and are deposited in such a way that the center-to-center spacing between adjacent masking nanoparticles can be controlled to a very high degree. Preparing nanostructures using the various methods described throughout using these masking nanoparticles translates to nanostructures that also have very uniform diameters and center-to-center spacings. Thus, in suitable embodiments the diameters of the nanostructures are between about 1-20 nm, suitably between about 1-15 nm, about 1-10 nm, or about 1-5 nm, e.g., about 2 nm, about 3 nm, about 4 nm, about 5 nm, about 6 nm, about 7 nm, about 8 nm, about 9 nm, or about 10 nm. Suitably, the size distributions of the nanostructures produced by the methods of the present invention are no greater than about 30% of a mean diameter of the nanostructures, and suitably, no greater than about 20%, no greater than about 15%, no greater than about 12%, no greater than about 10%, no greater than about 8%, no greater than about 6%, or no greater than about 5%. As used herein, the phrase “size distributions” as it relates to the diameter of the nanostructures and/or masking nanoparticles means that diameters of the nanostructures/masking nanoparticles are within a specified percentage (e.g., 20% greater or 20% less than) of the mean diameter of the population of nanostructures/masking nanoparticles.

In addition, the center-to-center spacing between adjacent nanostructures is suitably between about 1-20 nm, suitably about 1-15 nm, about 1-10 nm, or about 1-5 nm, e.g., about 2 nm, about 3 nm, about 4 nm, about 5 nm, about 6 nm, about 7 nm, about 8 nm, about 9 nm, or about 10 nm. Suitably, the center-to-center spacing is controlled to comprise a variance of about 10%, for example, between about 5-20%, about 7-15% or about 8-12%. As used herein, the phrase “variance” as it relates to the center-to-center spacing between adjacent nanostructures and/or masking nanoparticles means that the center-to-center spacings between nanostructures/masking nanoparticles are within a specified percentage (e.g., 20% greater or 20% less than) of the mean center-to-center spacings of the population of nanostructures/masking nanoparticles.

In further embodiments, the present invention provides field effect transistors comprising the various nanostructures described throughout. For example, a field effect transistor of the present invention suitably comprises a source region and a drain region formed in a semiconductor material. A channel region is disposed between the source region and the drain region and an insulating layer of electrically insulating material is disposed over the channel region. Suitably, a floating gate layer of electrically conducting material is disposed over the insulating layer and a layer of electrically insulating material is disposed over the floating gate layer. A gate electrode then overlays the layer of insulating material. In suitable embodiments, the floating gate layer comprises a plurality of discrete nanostructures produced by the various processes of the present invention. For example, the discrete nanostructures are electrically conducting nanostructures that comprise diameters between about 1 nanometer and about 10 nanometers, with size distributions no greater than about 15% of a mean diameter of the nanostructures, and suitably comprise center-to-center spacings between adjacent nanostructures that are between about 1 nanometer and about 10 nanometers, where the center-to-center spacing controlled to comprise a variance of about 10%. Exemplary electrically conducting materials for use as floating gate layer nanostructures are described herein, including, but not limited to, palladium (Pd), iridium (Ir), nickel (Ni), platinum (Pt), gold (Au), ruthenium (Ru), cobalt (Co), tungsten (W), tellurium (Te), rhenium (Re), molybdenum (Mo), iron platinum alloy (FePt), tantalum nitride (TaN), etc.

Methods for forming and using field effect transistors (FETs), including suitable materials for use in the various components/layers of FETs can be found, for example, in Sze, S. M., Physics of Semiconductor Devices, 2^{nd} Edition, John Wiley & Sons, New York, Chapter 6 (1981), the disclosure of which is incorporated by reference herein in its entirety.

In further embodiments, the present invention provides field effect transistors comprising the various regions and layers described throughout, wherein the floating gate layer comprises a plurality of discrete electrically conducting nanostructures prepared by the various processes of the present invention. For example, the nanostructures for use in the FETs are prepared by disposing one or more masking nanoparticles on an electrically conducting substrate, wherein the nanoparticles cover at least a portion of the substrate. Then, uncovered substrate material is removed (e.g., via etching), thereby forming electrically conducting substrate nanostructures at sites of the masking nanoparticles, and then the masking nanoparticles are removed.

In still further embodiments, exemplary FETs of the present invention comprise the various regions and layers described throughout, wherein a floating gate layer of electrically conducting material is disposed in the insulating layer. In suitable such embodiments, the floating gate layer comprises a plurality of discrete electrically conducting nanostructures prepared by a process comprising disposing a negative photo-resistant layer on the insulating layer. One or more masking nanoparticles are then disposed on the negative photo-resistant layer, wherein the nanoparticles cover at least a portion of the negative photo-resistant layer. One or more uncovered portions of the negative photo-resistant layer resistant are then reacted to form one or more etch masks comprising one or more portions of reacted negative photo-resistant layer and one or more portions of un-reacted photo-resistant layer. The masking nanoparticles are then removed, thereby revealing the one or more portions of un-reacted negative photo-resistant layer, and the un-reacted portions of the photo-resistant layer are removed, thereby revealing one or more exposed insulating layer sections. At least a portion of the one or more exposed insulating layer sections is removed, thereby forming nanoscale cavities in the insulating layer, and an electrically conducting filler material is disposed in the nanoscale cavities. Then, excess filler material that is above the plane of the insulating layer is removed, thereby forming one or more electrically conducting nanostructures in the nanoscale cavities of the insulating material.

In additional embodiments, exemplary FETs of the present invention comprise the various regions and layers described throughout, wherein a floating gate layer of electrically conducting material is disposed in the insulating layer. In suitable such embodiments, the floating gate layer comprises a plurality of discrete electrically conducting nanostructures prepared by a process comprising disposing one or more masking nanoparticles on a substrate, wherein the nanoparticles cover at least a portion of the substrate. Uncovered substrate material is then removed, thereby forming substrate pillars at the portion of the substrate covered by the masking nanoparticles, and forming substrate cavities at a portion of the substrate not covered by the masking nanoparticles. The masking nanoparticles are removed, and an insulating layer of electrically insulating material is disposed on the pillars and at least partially in the cavities, wherein a pit is maintained at the site of the cavities. An electrically conducting filler material is then disposed on the insulating layer, wherein the filler material forms electrically conducting nanostructures confined to the pits.

### Phase Change Materials and Transistor Switches

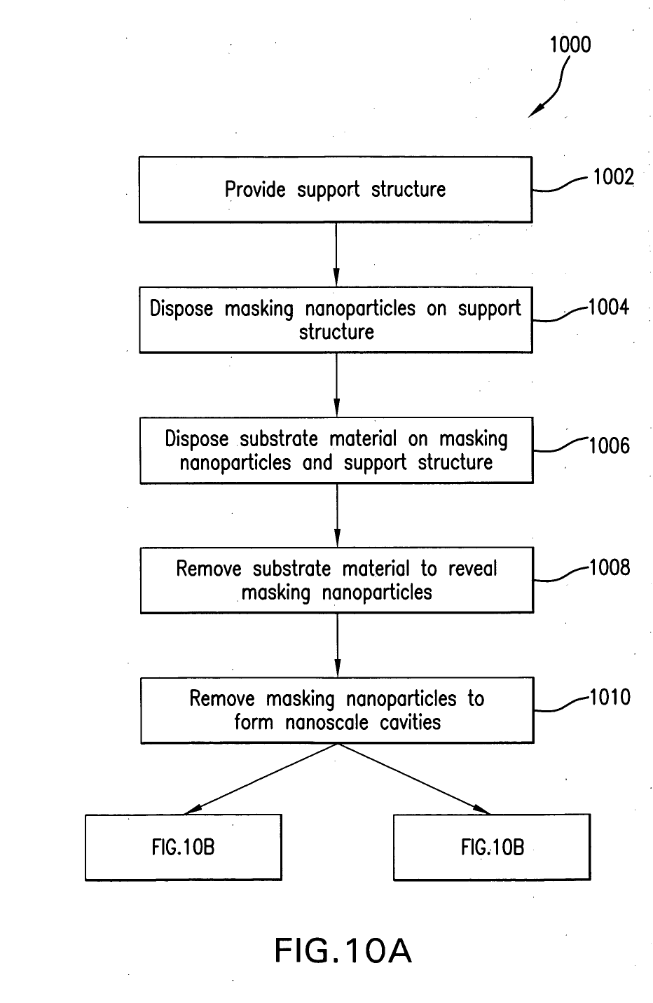

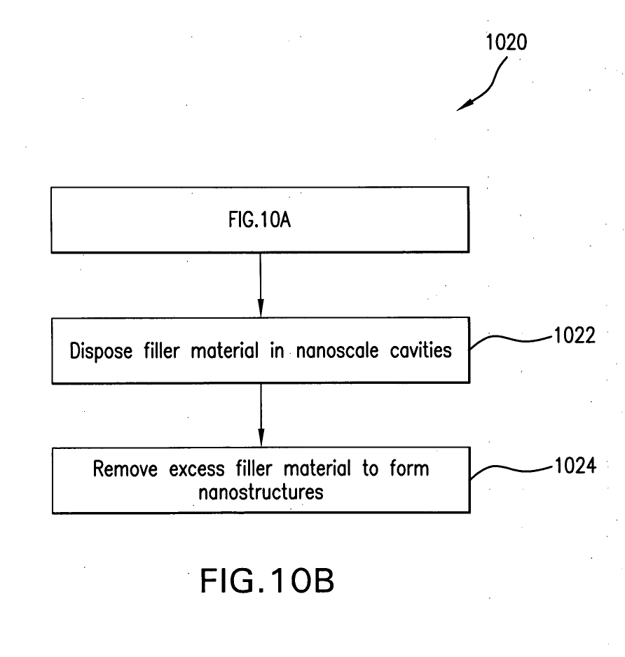

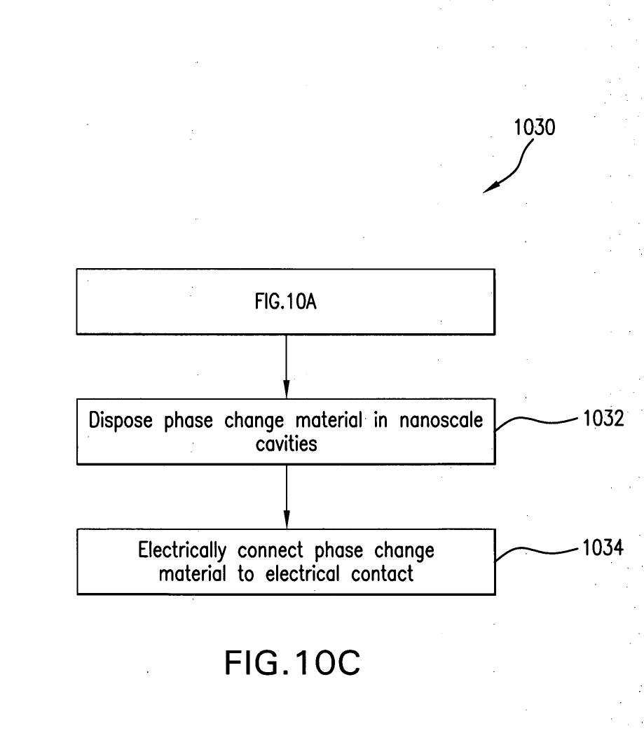

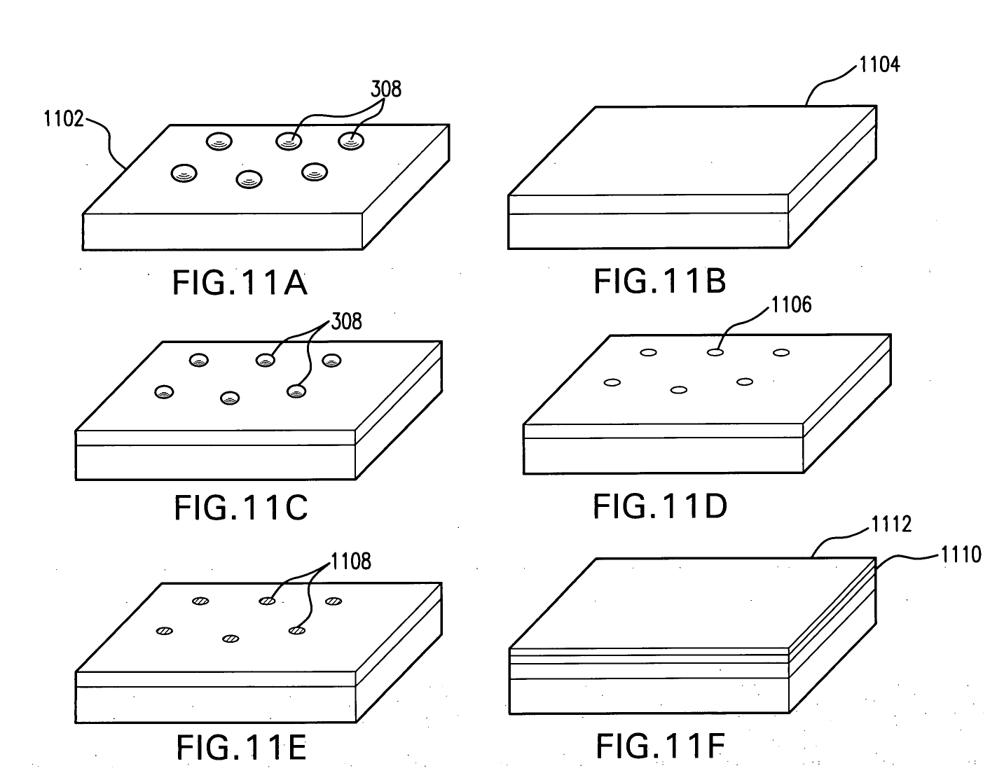

The present invention also provides further methods of generating nanoscale cavities, and nanoscale cavities generated by such methods. Exemplary embodiments are illustrated in flowchart 1000 of FIG. 10A with reference to FIGS. 11A-11F. As shown in step 1002 of FIG. 10A, a support structure 1102 is provided. Support structure 1102 can comprise any suitable material, including metals, semiconductors, polymers, insulators, etc. In exemplary embodiments, support structure 1102 is an electrically conductive material, such as a metal, including, but not limited to W, WN₂, TaN, and Iridium.

In step 1004 of flowchart 1000, one or more masking nanoparticles 308 are disposed on support structure 1102, as shown in FIG. 11A. Exemplary methods for disposing masking nanoparticles (e.g., spin coating), as well as types and sizes (e.g., about 1-10 or about 1-5 nm) of masking nanoparticles for use in the practice of the present invention are described throughout. In step 1006 of flowchart 1000, a substrate material 1104 is then disposed on masking nanoparticles 308 and support structure 1102, thereby covering masking nanoparticles 308, as shown in FIG. 11B. As represented in FIG. 11B, substrate 1104 suitably completely covers masking nanoparticles 308. While substrate 1104 is represented as a substantially flat layer of disposed material, in many cases, small mounds or variations in substrate 1104 may occur where the substrate is covering masking nanoparticles 308. Exemplary substrate materials 1104 include electrically conducting materials, dielectric materials, semiconductor materials, insulators and the like. For example, substrate material 1104 can comprise silicon dioxide or alumina. Methods for disposing substrate material 1104 in step 1006 include spray coating, layering, physical vapor deposition, chemical vapor deposition, evaporation and the like.

In step 1008 of FIG. 10A, at least a portion of substrate material 1104, is then removed, thereby revealing at least a portion of masking nanoparticles 308, as shown in FIG. 11C. Exemplary methods for removing substrate 1104 include, but are not limited to physical methods, such as chemical, mechanical or chemical-mechanical polishing and planing, as well etching as described throughout, including various chemical etching methods, as well as RIE etching and electron beam etching. Suitably, removal step 1008 is performed by a mechanical or chemical-mechanical process, such as polishing or planing. U.S. Pat. No. 5,527,423, for example, (the disclosure of which is incorporated by reference herein in its entirety) describes a method for chemically-mechanically polishing a metal layer by contacting the surface with a polishing slurry comprising high purity fine metal oxide particles in an aqueous medium. The polishing slurry is typically used in conjunction with a polishing pad (e.g., polishing cloth or disk). Suitable polishing pads are described in U.S. Pat. Nos. 6,062,968, 6,117,000, and 6,126,532 (the disclosures of which are incorporated by reference herein in their entireties), which disclose the use of sintered polyurethane polishing pads having an open-celled porous network, and U.S. Pat. No. 5,489,233 (the disclosure of which is incorporated by reference herein in its entirety), which discloses the use of solid polishing pads having a surface texture or pattern. Alternatively, the abrasive material may be incorporated into the polishing pad. U.S. Pat. No. 5,958,794 (the disclosure of which is incorporated by reference herein in its entirety) discloses a fixed abrasive polishing pad.

Removing at least a portion of substrate 1104 so as to reveal at least a portion of masking nanoparticles 308 provides access to masking nanoparticles 308, while still maintaining substrate material 1104 surrounding the nanoparticles. Then, in step 1010 of flowchart 1000, masking nanoparticles 308 are removed. As shown in FIG. 11D, removal of masking nanoparticles 308 forms nanoscale cavities 1106 in substrate 1104 at the sites once occupied by the masking nanoparticles 308. By selectively removing just the masking nanoparticles 308, but not removing or otherwise substantially impacting substrate 1104, cavities 1106 are left in substrate 1104 where the masking nanoparticles 308 were. Selective removal of masking nanoparticles 308 in step 1010 requires selection of a proper removal method, for example, a selective etch that removes masking nanoparticles 1104, but does not substantially impact substrate 1104. Exemplary methods of etching, including chemical, RIE and electron beam etching, are described throughout. While it is desirable to not remove any substrate 1104 during step 1010, removal of some substrate material is acceptable, and may allow for the formation of larger nanoscale cavities in substrate 1104.

As discussed throughout, the size of masking nanoparticles is suitably between about 1-20 nm, about 1-10 nm, or about 1-5 nm. Thus, the method shown in flowchart 1000 suitably generates nanoscale cavities 1106 that are between about 1-20 nm, about 1-10 nm, or about 1-5 nm, as it is the diameter of the masking nanoparticles that ultimately determines the size of nanoscale cavities 1106. As discussed above, the depth of nanoscale cavities 1106 is controlled by the extent of removal/etch of substrate 1104. In suitable embodiments, substrate 1104 is removed down to the level of support layer 1102.

In still further embodiments, the present invention provides methods for generating one or more nanostructures utilizing nanoscale cavities 1106. Following the formation of nanoscale cavities in a substrate 1104 as shown in FIG. 10A, one or more nanostructures can be prepared using these nanoscale cavities 1106, as shown in flowchart 1020 of FIG. 10B. For example, in step 1022, a filler material is disposed in the nanoscale cavities 1106, as shown in FIG. 11E. Then, any excess filler material that is above the plane of the substrate material 1102 is removed in step 1024, thereby forming one or more nanostructures 1108 in the nanoscale cavities 1106. Suitable methods for disposing filler material in the nanoscale cavities 1106 are described throughout, including chemical vapor deposition, physical vapor deposition and evaporation. Exemplary filler materials include semiconducting material, electrically conducting/conductive material (e.g., metals, polysilicon), insulator material, etc. Methods for removing excess filler material are also described throughout, including various forms of planing and/or etching.

In further embodiments, a nanoscale phase change layer can be generated by disposing a phase change material 1110 in at least the nanoscale cavities 1106, as shown in step 1032 of flowchart 1030 of FIG. 10C. As used herein, the terms “phase change material,” “phase change layer,” “phase change memory (PCM) material” and “phase change memory (PCM) layer” are used interchangeably to mean a material that is capable of being converted from a crystalline (conductive) to an amorphous (resistive) state via the application of external energy, suitably in the form of heat. A phase change material is a substance with a high heat of fusion which, upon melting and solidifying at certain temperatures and at certain rates, is capable of storing or releasing large amounts of energy.

Exemplary phase change materials include salt hydrides, fatty acids and esters, and various paraffins (such as octadecane). One exemplary phase change material for use in the practice of the present invention is chalcogenide (a glass containing a chalcogenide element, such as sulfur, selenium or tellurium), including an alloy of germanium, antimony, and tellurium (GeSbTe). Rapid heating and cooling above the melting point (about 600° C.) of this material forms a high resistance amorphous glass, while slow annealing above the crystallization point (about 400° C.), but below the melting point, forms a low resistance crystal. Heating of the phase change material, e.g., ohmic heating (I²R) is used to transition states, for example from high resistance, amorphous state (reset) to low resistance, crystalline state (set). Heating rates are on the order of 5 ns, representing write times approximately 100,000 times faster than Flash memory. In addition, the lifetime write/erase cycles for PCM are on the order of 10¹², far outdistancing Flash memory, where lifetime is limited to 100,000 write/erase cycles.

In suitable embodiments, a phase change material is disposed in at least the nanoscale cavities 1106 by chemical vapor deposition, physical vapor deposition or evaporation. As represented in FIG. 11E, deposition of a filler material (in this case a phase change material such as chalcogenide) generates nanostructures 1108 of these materials in the substrate material 1104. In exemplary embodiments, deposition of chalcogenide in nanoscale cavities 1106 on top of an electrically conductive (e.g., metallic) support layer 1102 allows for direct contact between the chalcogenide and the support layer. As the size of the masking nanoparticles are on the order of 1-20 nm, the size of the contact area between the chalcogenide and the support layer is also on this same size scale. Reducing the contact area to nanoscale dimensions (e.g., 1-20 nm, or about 1-10 nm) allows for the use of very low amounts of current to transition the phase change material between amorphous and crystalline states.

Thus, in further embodiments, as shown in FIG. 10C, electrically connecting the phase change material 1110 to an electrical contact in step 1034 of flowchart 1030, allows for the production of a PCM cell, as shown in FIG. 11F. Suitably, the phase change material 1110 is connected to an electrical contact by disposing an electrically conductive material 1112 (e.g., a metal or polysilicon layer) on the nanoscale phase change layer. This electrically conductive material is then connected to an electrical connection. In order to transition the phase change material 1110 from amorphous to crystalline, an electric current is provided between electrically conductive material 1112 and an electrically conductive support layer 1102. The contacts between electrically conductive support layer 1102 and phase change material 1110 are confined to nanoscale contacts (on the order of 1-20 nm), as any additional phase change material 1110 is separated from support layer 1102 by the presence of substrate 1104 (e.g., an insulator). Current therefore suitably flows between electrically conductive material 1112 and support layer 1102 through phase change material nanostructures 1108, thus controlling the amount of phase change material that is transitioning between amorphous and crystalline states during heating. PCM cells produced in accordance with the present invention would reduce the area of the memory cell as compared to traditional PCM applications, and also reduce the effective area of the phase change material, therefore requiring less current than traditional PCM applications.

In further embodiments, the present invention provides methods for producing one or more nanowires as well as nanowires produced by these methods. The nanowires generated in accordance with the present invention are suitably at least 20 nm in length. As discussed herein, nanostructures (e.g. nanoparticles) of the present invention can be used for charge storage, as used in the floating gate of non-volatile memory (NVM) cells. Nanowires of the present invention are suitably used for conducting a current. Conducting a current allows the nanowires to be used as electrical conductors, electrical connectors, channels in semiconductor devices, and electron emitters.

Nanowires of the present invention can be used as emitters, for example, when prepared from (111) oriented diamond film. Thin diamond film can be grown in a plasma reactor. Preparation of single crystal grain boundaries several orders of magnitude greater than the diameter of a single nanowire are possible. Nitrogen doping makes the diamond n type, and with hydrogen treated tips, is characterized by a negative electron affinity. The diamond tip, in combination with its negative electron affinity, makes for a suitable electron emitter.

The present invention also provides one or more nanowires comprising an insulating material. Applications include mechanical conditioning of substrate materials and/or layers of substrate materials. The mechanical properties of the nanowires can be used to strengthen or weaken, toughen, or increase flexure and reduce shock in a multilayer substrate. Increasing flexure in multilayer substrates is particularly advantageous in environments with high temperature gradients, common to processing environments.

The present invention also provides one or more nanowires comprising a combination of insulating, conducting, and semiconducting materials. As an example, the nanowire construction could itself contain alternating conductive and insulating layers, such that the conducting layers function as nanoparticles. As another example, constructing a nanowire by alternately doping semiconducting material allows the nanoparticle to function as a transistor, or a series of transistors. Exemplary embodiments provide structure and construction of one or more nanowires and a surrounding medium that allow the set of embodiments to function as one or more transistor switches.

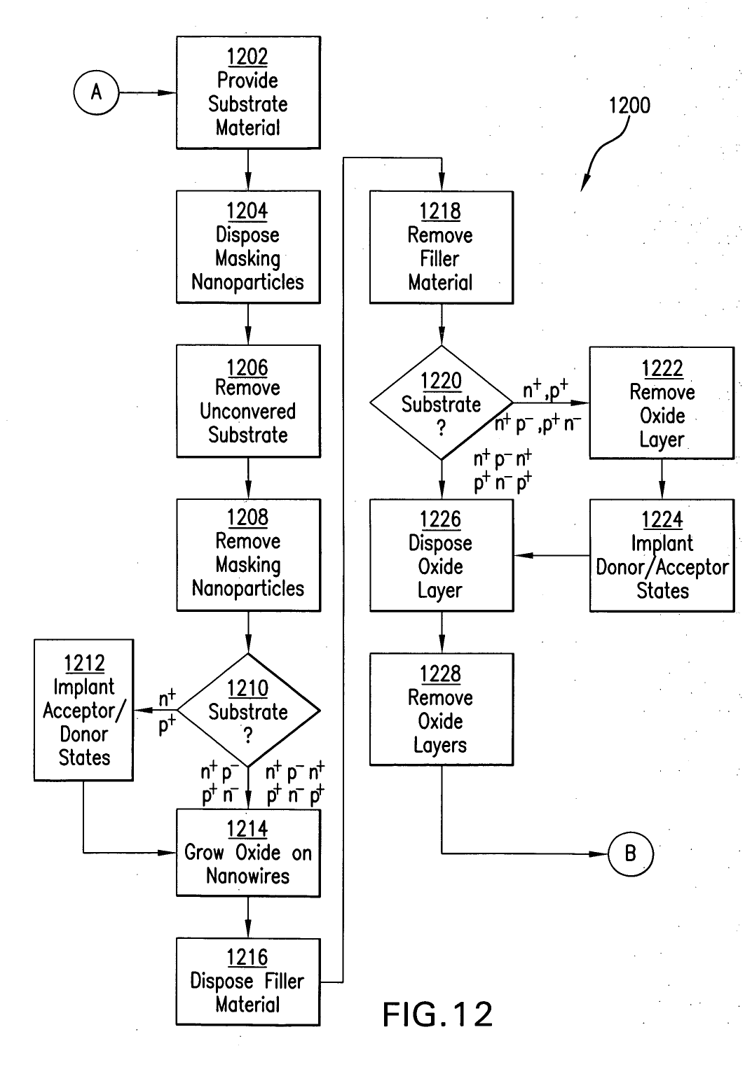

Exemplary methods for producing nanowires in accordance with the present invention are provided in FIG. 12, flow chart 1200. The first four steps in flow chart 1200 generate one or more nanowires, which are later used in generating one or more transistor switches, as discussed below.

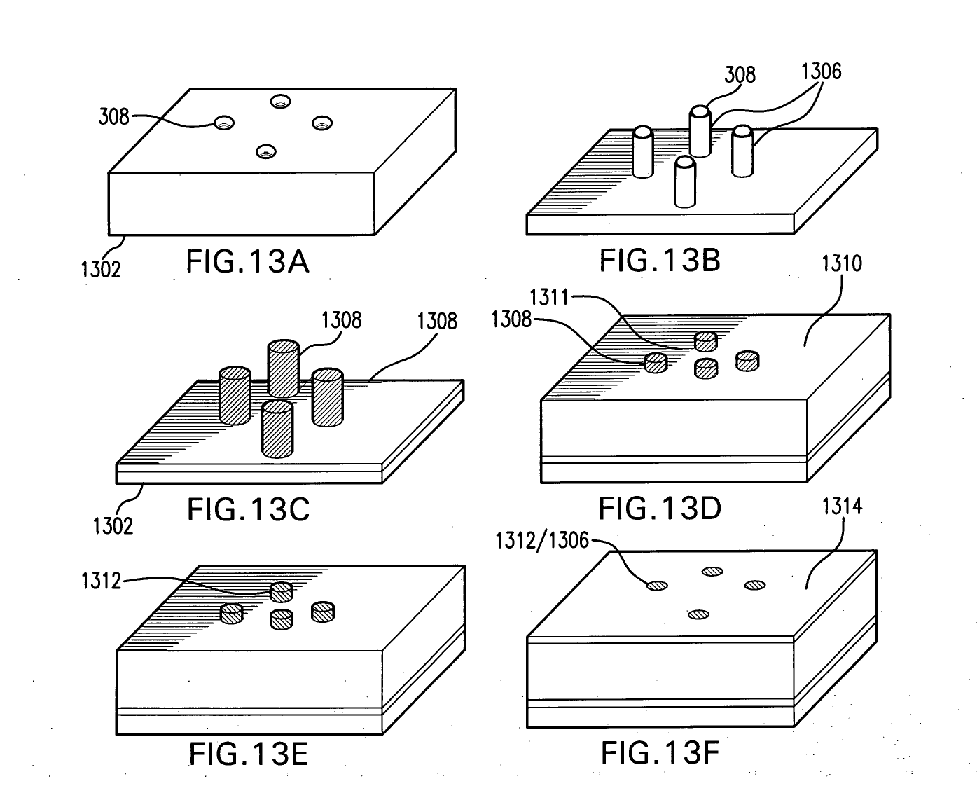

In step 1202, a substrate 1302 is provided, as shown in FIG. 13A. The substrate can be a conducting, semiconducting, or insulating material, or any combination of conducting, semiconducting, and insulating materials, or any combination of doped semiconductor material or materials. In step 1204, one or more masking nanoparticles 308 are disposed on the substrate surface. The masking nanoparticles can be spin coated onto the substrate surface, spreading an evenly distributed monolayer of masking nanoparticles, as show previously in FIGS. 1A-1C. The masking nanoparticles can comprise elements including, but not limited to, Pd, Ni, Ru, Co, and Au. The masking nanoparticles are suitably spherical in shape, with uniform diameters between about 1-5 nm, or between about 1-10 nm, though other shapes and sizes can be used.

In step 1206 of flowchart 1200, the regions of the substrate that are not covered, or masked, by the masking nanoparticles are removed. Removing the unmasked regions of the substrate to a depth of about more than about 20 nm, suitably in a direction about normal to the substrate surface, leaves the substrate material under the masking nanoparticles 308, as shown in FIG. 13B. As a result, removing the unmasked regions of the substrate material to a depth of about greater than 20 nm, followed by step 1208, which removes the masking nanoparticles themselves, for example, by rinsing in a solvent, leaves uniformly spaced nanowires 1306, suitably with a height about greater than 20 nm.

Removing the unmasked substrate material in a direction about normal to the substrate surface suitably uses a removing technique that is directional; that is, the removing is anisotropic, rather than isotropic, though isotropic removal can also be used.

One method that removes substrate material anisotropically is reactive ion etching (RIE). As discussed herein, RIE etches by chemical reaction, where the etching ion reacts with the substrate surface, in a direction normal to the substrate surface. In RIE, the reaction rate is increased at the substrate surface where the substrate bonds are weakened or broken by ion and/or neutral bombardment. Neutral bombardment is isotropic, and functions both independently of, and in conjunction with, ion bombardment.

Ion bombardment is anisotropic; ions are directed to a line of flight normal to the substrate surface by an applied potential, or a potential set up by the etching system. The impact energy level of the ion atom with the substrate surface is determined by the substrate surface potential. The impact energy level is critical to determining etch rate and directionality. Increasing the impact energy in RIE increases directionality in the etch, but can increase the damage caused to surrounding substrate material.

A second etching technique, electron beam etching, allows for etching down to about 1 nm. Electron beam etching is anisotropic, and like RIE, impact energy is controllable by setting the appropriate substrate potential. Unlike RIE, electron beam etching does not etch by chemical reaction; electron beam etching breaks bonds by impact and collisions.

In exemplary embodiments, nanowires produced by the methods of the present invention, as discussed above, in steps 1202-1208, flow chart 120, are suitably used to generate one or more transistor switches. In embodiments for generating one or more transistor switches, substrate 1302 provided in step 1202 can be an n⁺p⁻n⁺ or p⁺n⁻p⁺ epitaxial semiconductor substrate, as represented in decision tree step 1210 of flow chart 1200. In this case, substrate 1302 has been grown such that nanowires 1306 produced in steps 1202-1208 are affixed to a heavily doped n⁺ or p⁺ substrate, with a lightly doped p⁻ or n⁻ channel region that extends to nearly the top of the nanowire (i.e., greater than about 20 nm), where a small, heavily doped n⁺ or p⁺ region comprises the top of the nanowire. As used herein, doping refers to growing or implanting a substrate, such as silicon, with dopant atoms that have a greater number of electrons (n-type, n) or a fewer number of electrons (p-type, p) necessary to bond with the substrate material. For example, the concentration of atoms in a silicon crystal is approximately 5×10²³/cm³. The intrinsic carrier concentration of silicon at room temperature is approximately 1×10¹⁰/cm³.

Doping at concentrations of approximately 1×10¹³/cm³ to 5×10¹⁵/cm³, or one dopant atom per 5×10¹⁰ crystal atoms to one dopant atom per 1×10⁸ crystal atoms are considered lightly doped (n⁻, p⁻). Lightly doped semiconductors are used when it is necessary to flow current using minority carriers, as in the inversion layer of a MOSFET.

Doping at concentrations of approximately 5×10¹⁷/cm³ and higher, or one dopant atom per 1×10⁵ crystal atoms, are considered heavily doped (n⁺, p⁺). All of the electrons in a heavily doped semiconductor are in the conduction band at room temperature; n⁺ and p⁺ doped semiconductors behave as metals.

The resulting nanowires of the present invention can be generated directly by masking and etching, as described in steps 1202-1208 of flow chart 1200, an n⁺p⁻n⁺ or p⁺n⁻p⁺ epitaxial semiconductor substrate 1302. The bottom layer, of arbitrary thickness, is suitably a heavily doped n⁺ or p⁺ epitaxially grown semiconductor material. The deposition layers that follow, the lightly doped p⁻ or n⁻ channel region and the heavily doped n⁺ or p⁺ region on top, are suitably about greater than 20 nm and about 1-5 nm, respectively.

Continuing in flow chart 1200, an oxide layer 1308 is grown on exposed semiconductor material (e.g. substrate 1302 and nanowires 1306) in step 1214, as shown in FIG. 13C. In the case of an epitaxially grown silicon substrate, oxygen is suitably infused in a near vacuum at temperatures of about 900° C., whereby a layer of silicon dioxide (SiO₂) grows isotropically on exposed surfaces, providing an insulating oxide layer on both the one or more nanowires 1306 and the substrate 1302 surface between nanowires.

In step 1216, a filler material 1310 is disposed on the previously grown oxide layer 1308, as shown in FIG. 13D. Filler material 1310 can be deposited by chemical vapor deposition (CVD), physical vapor deposition (PVD), evaporative methods, or other suitable methods. The deposited filler material fills the voids or cavities between the uniformly space nanowires 1308. In methods of generating one or more transistor switches, the filler material is electrically conductive, for example, metal or polysilicon.

In step 1218, filler material 1310 is removed, for example, by using an isotropic etch to form cavities 1311, as shown in FIG. 13D. The filler material is removed such that, when step 1218 is completed, the filler material will form a “sea” about 1-4 nm below the tops of the one or more nanowire “islands” it contains. In step 1226, provided that an n⁺p⁻n⁺ or p⁺n⁻p⁺ epitaxial semiconductor substrate 1302 has been supplied as determined in decision tree step 1220, an oxide layer 1314 or insulating layer is disposed, filling cavity 1311 in filler material 1310, as well as filling over the top of the one or more nanowires 1306. The oxide or insulating layer 1314 is then partially removed, for example, by isotropically etching, revealing the top surface 1312 of the one or more nanowires 1306.

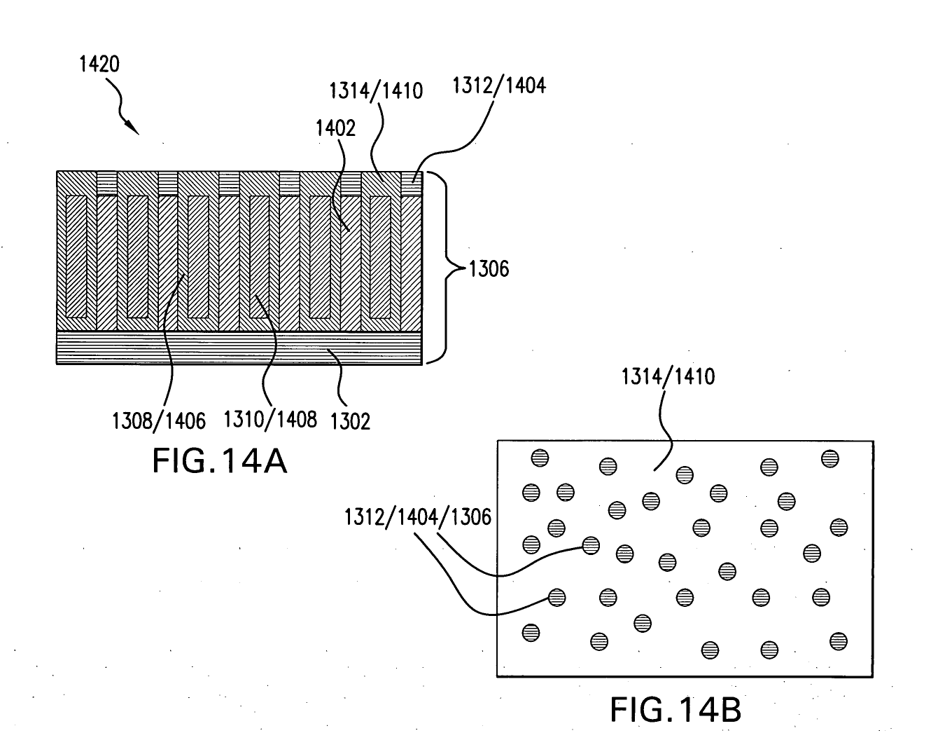

At this point, generation of one or more transistor nanowires 1306 is complete. The n⁺p⁻n⁺ or p⁺n⁻p⁺ epitaxial semiconductor substrate 1302 that has been turned into the one or more n+p⁻n+ or p+n⁻p+nanowires represents the source (original base of substrate 1302), channel region 1402, and drain 1404 (top 1312 of nanowires 1306), respectively, of a field effect transistor (FET), as shown in FIG. 14A. The oxide layer 1308 that covers and insulates each of the one or more nanowires acts as a gate oxide 1406, and taken with the conductive filler material 1310 that acts as the gate 1408, completes the basic architecture for a standard metal oxide semiconductor field effect transistor (MOSFET).

When energized, i.e., when a potential is applied to the gate 1310/1408, a conducting channel is formed at the outer circumference of the nanowire. Each gate is interconnected to every other gate, as the conductive filler material forms a continuous “sea” 1408 that surrounds “islands” of n or p channel nanowires 1306.

In another embodiment, the substrate provided 1302 in step 1202 can be an n⁺p⁻ or p⁺n⁻ epitaxially grown semiconductor substrate, for example an n⁺p⁻ or p⁺n⁻ epitaxially grown silicon substrate. The dimensions of the n+ and p⁻ regions, or of the p⁺ and n⁻ regions, are suitably identical to the dimensions given in the previous embodiment. Method steps 1202-1220, from flow chart 1200, proceed as above, where the substrate provided in the previous embodiment was an n⁺p⁻n⁺ or p⁺n⁻p⁺ epitaxially grown semiconductor substrate.

In the previous embodiment, the tops of the one or more nanowires 1306 were heavily doped n⁺ or p⁺, as provided by the substrate material 1302. In the present embodiment, this is no longer the case. The n⁺ or p⁺ regions must be generated. The decision tree step 1220 directs the next step in the method sequence to remove the oxide layer 1308 that was grown on top of each of the one or more nanowires 1306 in step 1214. Step 1222 removes the existing oxide 1308 or insulating layer from the top of the one or more nanowires, for example by isotropically etching away the top portion of the oxide layer. Step 1224 n⁺ or p⁺ dopes the tops 1312 of the one or more nanowires 1306, as shown in FIG. 13E. Step 1220 then fills in cavities 1311 with an oxide or insulating material 1314, as described in the previous embodiment, shown in FIG. 13F. The oxide deposition and removal in steps 1226 and 1228, respectively, are identical to steps 1226 and 1228 in the previous embodiment.

The n⁺ or p⁺ doping in step 1224 is suitably performed by ion implantation. High energy ions penetrate the exposed nanowire tops 1312. Performing the donor or acceptor ion implant step in a high temperature vacuum allows donor or acceptor ions to diffuse into the nanowires, generating the donor or acceptor band levels for semiconduction. The exposed conductive filler material 1310 is also penetrated by donor or acceptor ions in step 1224. However, given the filler material is conducting, there no net effect on the filler material.

In another embodiment, the substrate provided 1302 is an n⁺ or p⁺ epitaxially grown semiconductor substrate, for example an n⁺ or p⁺ epitaxially grown silicon substrate. Method steps 1202-1210 and 1214-1228 are identical to the previous embodiment, where the substrate provided in the previous embodiment was an n⁺p⁻ or p⁺n⁻ epitaxially grown semiconductor substrate. The decision tree step 1210 directs the next step in the method sequence to implant acceptor or donor states into each one of the one or more nanowires 1306 in step 1212. In the previous embodiment, the one or more nanowires were lightly doped p⁻ or n⁻, as provided by the substrate material 1302. In the present embodiment, this is no longer the case. The p⁻ or n⁻ regions must be generated. Step 1212 provides the implant process.

Acceptor or donor states are suitably implanted by infusing acceptor or donor ion into the reactor chamber, where the acceptor or donor ions are accelerated to an energy high enough to be implanted on the nanowire surface 1306. The surface implant step is run in parallel with one or more heating and cooling temperature cycles applied to the substrate and nanowires, allowing the acceptor or donor ions lodged on the surface of the one or more nanowires to diffuse into the nanowires. The approximate even diffusion and distribution of the acceptor and donor ions into the nanowires allows for setting a sharp, consistent in-band energy level for acceptor or donor states.

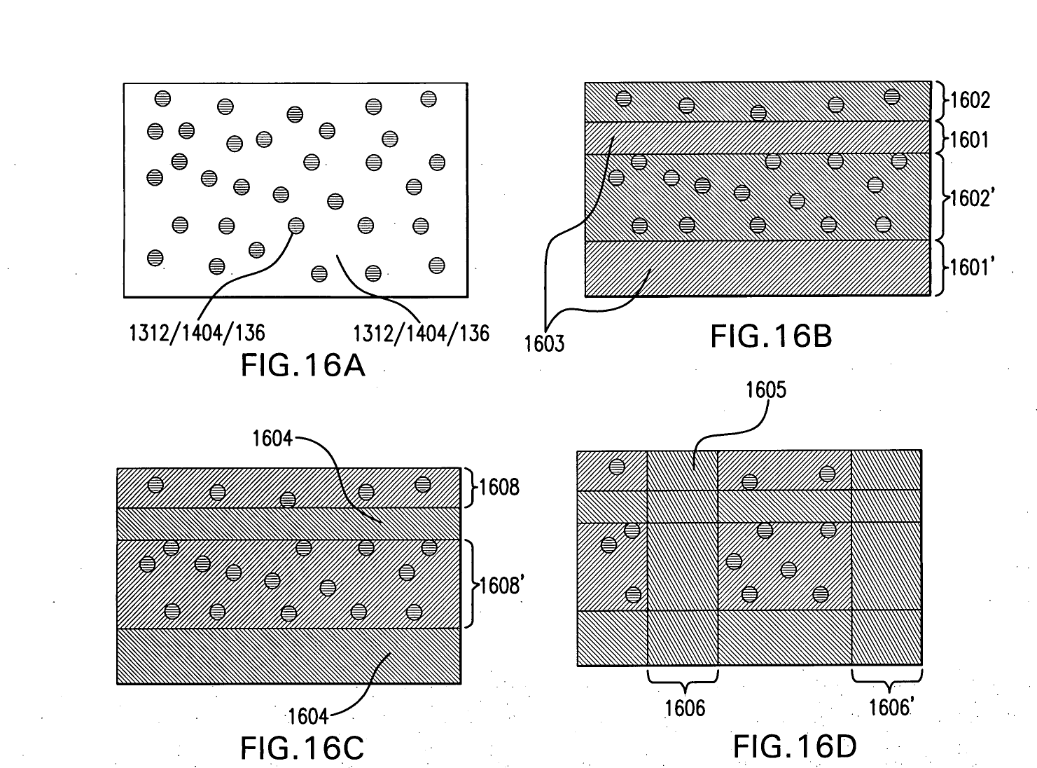

At the conclusion of step 1228, at label B in flow chart 1200, the generation of one or more transistor switches 1420 is complete. In the present embodiment, the transistor switches represent MOSFETs, as described previously. The ends of the one or more nanowires 1306 are exposed, as shown in FIG. 13F and FIG. 14A-B, and not covered by the oxide or insulator 1314 disposed in step 1226. The ends 1312 of the one or more nanowires act as drains 1404 for the one or more transistor switches. Keeping the ends of the one or more nanowires exposed allows for drain contacts, or bit lines 1606, shown in FIG. 16D, to be produced on the one or more transistor switches in subsequent steps, as described below.

At the conclusion of step 1228, at label B in flow chart 1200, the bulk conductive filler material 1310 acts as the gate 1408 for the one or more transistor switches 1420. Keeping the perimeter of the conductive filler material exposed allows for gate contacts, or word lines 1608, shown in FIG. 16C, to be produced on the one or more transistor switches in subsequent steps, as described below.

The present invention also provides methods for generating an array of two or more electrically connected transistor switches. One or more transistor switches are prepared as set forth above, starting at label A and terminating at label B, in flow chart 1200. As with previous embodiments, nanowire composition is a direct result of the provided substrate 1302 material and any subsequent doping that may have occurred.

Following the production of two or more transistor switches 1420, an array of transistor switches 1720, in this case MOSFETs, can be generated. The array of transistor switches 1720 comprises islands of vertical n channel or p channel nanowires 1306, surrounded by an insulating gate oxide 1308/1406, immersed in a sea of conductive filler material 1310, which acts as a collective gate 1408, interconnected to each of the MOSFETs in the array. The top 1312 of each vertical n channel or p channel nanowire acts as the drain 1404 for its respective MOSFET (refer to FIG. 16A). Gate connections, or word lines 1608, can be prepared by removing portions of the conductive filler material/gate 1310/1408 “sea” as well as nanowire 1306 islands in certain areas (e.g., sections 1601 in FIG. 16B), while leaving behind conductive filler material 1310 connecting the selected gates 1408, as shown in FIG. 16B (e.g., sections 1602 in FIG. 16B), and discussed below. In this way, word lines 1608 are embodied by the conductive filler 1310 material itself, eliminating the need for further deposition.

Drain connections, or bit lines 1606/1606′, are suitably made by deposition of a conductive material 1605 to the drains 1404 in the vertical MOSFETs, the i.e., exposed tops 1312 of the array of transistor switches 1420. Bit lines can be formed by standard photolithographic techniques. Bit lines connect subarrays of nanowire transistor switches that are connected by independent word lines.

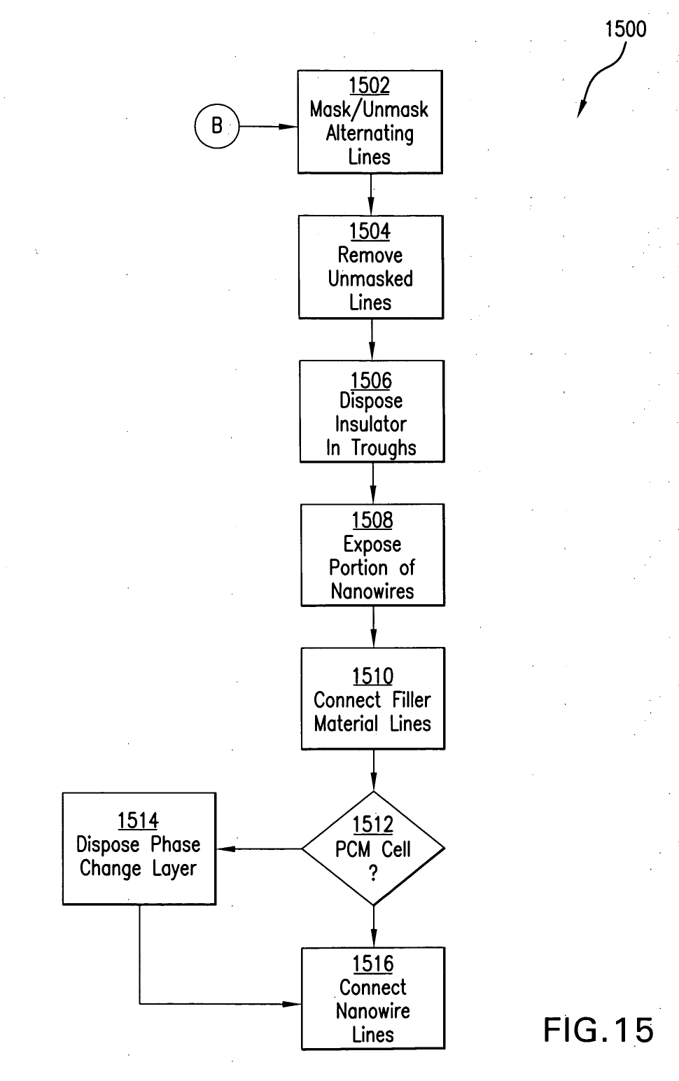

Exemplary methods for generating arrays of transistor switches are shown in FIG. 15, flowchart 1500. In step 1502 of flowchart 1500, masked and unmasked alternating lines are generated. As used herein “lines” means sections of transistor switches 1720 that are selected to be either utilized in the arrays of the present invention, or to be removed. Lines suitably will comprise filler material 1310 (i.e., gates 1408) as well as nanowire transistors 1306. In suitable embodiments, alternating lines are generated. That is, sections of transistor switches are masked, while adjacent sections are not masked. Alternating lines can be generated, for example, using standard photolithographic techniques in which a mask (e.g., an etch-resistant mask) is disposed on sections of transistor switches 1420 that are to be maintained/saved in the array (e.g., sections 1602), while other sections are not masked (e.g., sections 1601).

In step 1504 of flowchart 1500, a portion of the material under the unmasked lines is removed, as shown in FIG. 16B, to form troughs 1603. Removing material in step 1504 can be performed anisotropically, for example, by RIE. However, given up to hundreds of nanowire transistor switches in parallel comprise each connection, isotropic etching can be a suitable alternative. Isotropic etching can undercut the etch mask, and etch a portion, but not all, of the underlying nanowires and filler material. Suitably, the material under the masked lines is removed down to approximately the level of substrate 1302, though as long as gate/filler material 1310/1408 is removed, the troughs are of sufficient depth.

In step 1506, troughs 1603 that have been removed in step of 1504 are filled with an electrically insulating material 1604, for example, an oxide, as shown in FIG. 16C. The insulating material 1604 is then partially removed in step 1508, from sections 1602, leveling the oxide layer, removing the mask, and again exposing the top portion 1312, or drain 1404, of the nanowires 1306. A process used to remove the insulating material is a reactive ion etch (RIE). Isotropic etching is also possible.

Electrical connections (1702 and 1702′) to the conductive filler material segments 1310, the gates 1408, are made in step 1510 of flowchart 1500 to portions of transistor arrays 1602 that were originally masked (i.e., not removed in step 1504). Independent electrical connections are suitably made to an end of one or more of the electrically isolated gate segments. Connections can be made using standard photolithographic techniques. In one method, the entire transistor array can be masked, as well as both ends of the alternating insulating lines, and a metal or suitable conducting material can be deposited. Metal deposition can be performed by chemical vapor deposition (CVD), physical vapor deposition (PVD), evaporation, or other techniques. After the masking layer is removed, individual contacts are made to each contiguous gate region.

Next, in decision tree step 1512, in flow chart 1500, directs the step sequence to step 1516, to electrically connect nanowires 1306. Step 1510 exposes the nanowire drain regions 1404. Connecting drains 1404 of one continuous word line or gate segment 1608 to drains 1404 of at least one other independent continuous word line or gate segment 1608′ in step 1516 of FIG. 15, as shown in FIG. 16D, can be performed with standard photolithographic techniques, as described in the previous paragraph. For example, a continuous conducting layer 1605 can be disposed on transistor array 1720, and then selectively etched so as to generate bit lines 1606 and 1606′ connecting drain regions 1404 of nanowires 1306 from different word lines (1608 and 1608′). In further embodiments, regions of masked and unmasked transistor switches can be prepared as discussed above in alternating lines crossing word lines 1608 and 1608′. Then, a conductive layer 1605 can be disposed on the exposed nanowire tips 1312 to connect the drains 1404 of the nanowire transistors 1306 in the word lines.

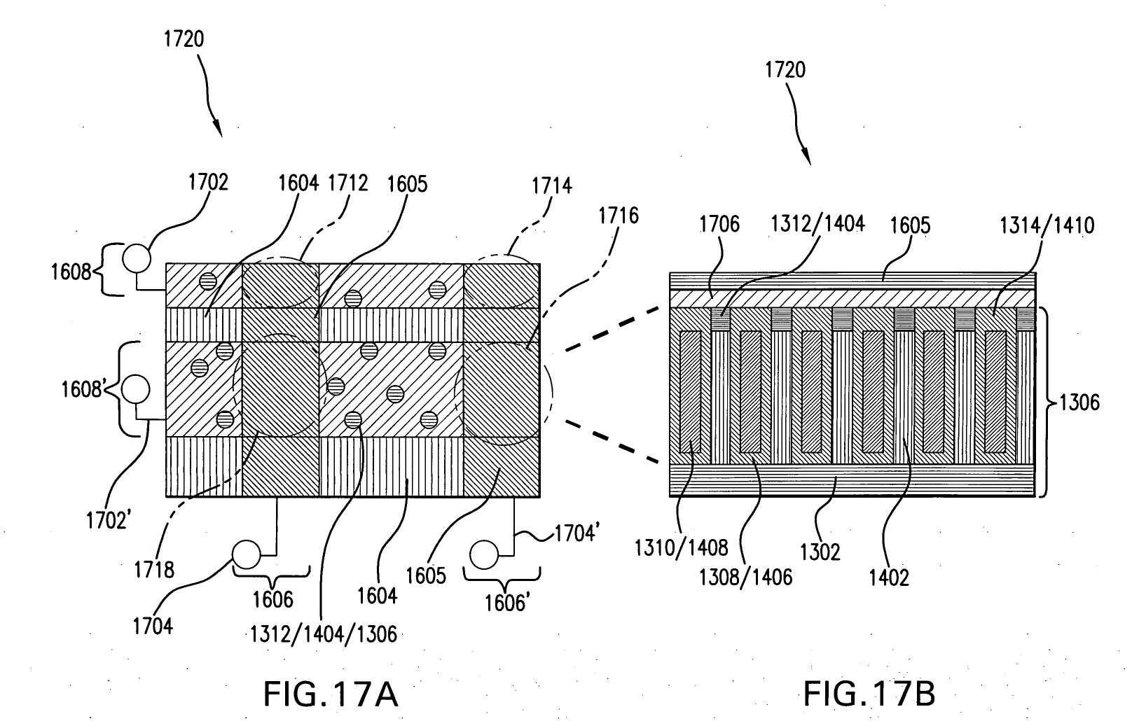

At the conclusion of step 1510, one or more contiguous and electrically isolated gate regions (e.g., 1608 and 1608′) are electrically connected to independent electrical connectors 1702/1702′, as shown in FIG. 17A. At the conclusion of step 1516, one or more contiguous and electrically isolated set of nanowire drain regions 1404 are electrically connected to independent electrical connectors 1704/1704′, shown in FIG. 17A. Gate and drain connections, commonly referred to as word and bit lines, respectively, can be made in any orientation, and suitably are made about orthogonal to each other. In this configuration, any one set of transistor switches (i.e., a cell 1710 comprising one or more nanowire transistors 1306 and gate regions 1408) can be individually addressed by row and column, associated with the bit and word lines, respectively.

In a further embodiment, the present invention comprises generating an array of two or more electrically connected PCM cells. An array of two or more electrically connected PCM cells can be generated by a nearly identical procedure as that used to generate an array of two or more electrically connected transistor switches, as discussed above, starting at label A and terminating at label B, in flow chart 1200 of FIG. 12, and continuing from label B through step 1516 in flow chart 1500 of FIG. 15.

Generating an array of two or more electrically connected PCM cells follows the steps of the preceding embodiment to decision tree step 1512 of FIG. 15, at which point a phase change material 1706 is disposed in step 1514, as shown in FIG. 17B. Exemplary phase change materials are described throughout, and include, for example, chalcogenide.

In additional embodiments, the present invention provides transistor switches 1420 as represented in FIGS. 14A and 14B. In exemplary embodiments, these switches comprise one or more transistor nanowires 1306 As described throughout, transistor nanowires 1306 suitably comprises a n⁺ doped substrate 1302 a p⁻ doped drain region 1402 and an n⁺ doped top 1312/1404 (e.g., n⁺p⁻n⁺ nanowires). As noted herein, transistor nanowires 1306 are suitably formed by removing (e.g., etching) substrate material 1302 so as to removed substrate that is not masked by masking nanoparticles 308. Substrate material 1302 can be pre-doped so as to comprise each n+ and p− section, or the nanowires can be formed and then doped after formation.

As shown in FIG. 14A, transistor switch 1420 also comprises an electrically conductive gate material 1310/1408 (e.g. polysilicon) surrounding the nanowires, and an insulating material 1308/1406 separating the nanowires 1306 from the electrically conductive gate material 1310/1408 As discussed throughout, and represented in FIGS. 14A and B, following formation of nanowires 1306 an insulating material 1308 is disposed on the nanowires. For example, an oxide is grown on the wires. When a filler material, e.g., an electrically conductive gate material 1310/1408 is then disposed on insulating material 1308 this gate material fills in around all of the nanowires, but is separated from the wires by insulating material 1308. As shown in FIG. 13F, electrically conductive gate material 1310 forms a “sea” of gate material 1408 throughout which nanowires 1306 are spaced. All gate material 1310 is connected together, and hence, by electrically connecting one portion of gate material 1310/1408 to an electrical connection 1702/1702′ as shown in FIG. 17A, all of gate material 1310 is therefore electrically connected. The transistor switches also further comprise an electrical connection to the nanowires, for example, as shown in FIG. 17A. In exemplary embodiments, the electrical connection to the nanowires 1306 is a layer of electrically conducting material 1605 disposed on the nanowires. Suitably an insulating material 1314/1410 (e.g., an oxide) separates the gate material 1310/1408 from the layer of electrically conducting material 1605. The transistor switches of the present invention suitably comprise a plurality of nanowire transistors, for example, 2 or more, 5 or more, 10 or more, 20 or more, 50 or more, 100 or more, 1000 or more, etc, nanowire transistors 1306 surrounded by gate material 1310/1408.

In further embodiments, the present invention provides PCM cells 1712, 1714, 1716, 1718, for example, as shown in FIG. 17B. Suitably, PCM cells 1712, 1714, 1716, 1718 comprise one or more transistor nanowires 1306. The PCM cells also comprise an electrically conductive gate material 1310/1408 surrounding the nanowires 1306 and a phase change material layer 1706 contacting at least a portion of at least one nanowire 1306. In order to separate both the electrically conductive gate layer 13108/1408 and the phase change material layer 1706 from the nanowires 1306, an insulating material 1314/1410 is suitably present between the nanowires and these various layers, as shown in FIG. 17B. In order to complete the PCM cell, an electrical connection is provided to the phase change material layer 1706, as shown in FIGS. 17A and B.

As discussed throughout, exemplary nanowires for use in the PCM cells of the present invention include n⁺p⁻n⁺ transistor nanowires, electrically conductive gate material 1310/1408 suitably comprises polysilicon, and insulating material 1308/1406 is suitably an oxide. As noted throughout, phase change material layer 1706 suitably comprises chalcogenide, though other phase change memory materials as known in the art and described herein can also be used. The PCM cells of the present invention suitably comprise a plurality of nanowires 1306, for example, 2 or more, 5 or more, 10 or more, 20 or more, 50 or more, 100 or more, 1000 or more, etc, nanowires surrounded by gate material 1310/1408.

As shown in FIGS. 17A and 17B, the electrical connection is suitably a layer of electrically conducting material 1605 disposed on the phase change layer 1706. This electrically conducting material 1605 is then connected to an electrical connection 1704/1704′ as shown in FIG. 17A.

The present invention also provides arrays of phase change memory cells. For example, as shown in FIG. 17 A, the arrays comprise at least two phase change memory cells 1712, 1714, 1716, 1718. Suitably, arrays of phase change memory cells comprise a plurality of PCM cells, for example, 2 or more, 5 or more, 10 or more, 20 or more, 50 or more, 100 or more, 1000 or more, etc. As noted above, the PCM cells each suitably comprise a plurality of nanowires 1306 surrounded by gate material 1310/1408. As shown in FIG. 17A, the arrays also comprise an insulating material 1604 separating the at least two PCM cells. As discussed above, insulating material 1604 is suitably disposed in troughs 1603 when preparing the PCM cell arrays. While FIG. 17A shows two PCM cells, (e.g., 1712 and 1718 or 1714 and 1716), separated from each other by insulating material 1604, arrays of the present invention can comprise any number of PCM cells as discussed throughout.

By insulating PCM cells from each other, the electrically conductive gate material 1310/1408 of a first PCM cell 1712 can be connected to a first electrical connection 1702, and electrically conductive gate material 1310/1408 of a second PCM cell 1718 can be connected to a second electrical connection 1702′. In this orientation, the gate material 1310/1408 of PCM cell 1712 can be addressed separately from the gate material 1310/1408 of PCM cell 1718 simply by turning on electrical connection 1702, but not electrical connection 1702′. As used herein the term “addressed separately” means that the gate material of each PCM cell can be electrically charged or discharged separately from another PCM cell (i.e., one cell is charged or discharged while another cell is not being charged or discharged). As used herein, electrically charging or discharging a cell comprises connecting the electrical connections of the present invention to a source of electric current.

As shown in FIGS. 17A-B, phase change layer 1706 of PCM cell 1712 can be connected to a third electrical connection 1704 and phase change layer 1706 of the PCM cell 1714 can be connected to a fourth electrical connection 1704′. Thus, in addition to addressing the gate materials of PCM cells separately, the phase change layer (and hence, the nanowires in contact with the phase change layer) can also be addressed separately. For example, as shown in FIG. 17 A, PCM cell 1712 can be addressed by charging or discharging the cell through electrical connection 1704 and PCM cell 1714 can be addressed by charging or discharging electrical connection 1704′.

In further embodiments, the present invention provides for individually addressable PCM cell sections. That is, individual PCM cells (1712, 1714, 1716, 1718) can be separately addressed by charging the gate material of a first PCM cell (e.g., by charging electrical connection 1702, and hence addressing PCM cells 1712 and 1714) and by charging phase change material, e.g., by charging electrical connection 1704, and hence addressing PCM cell 1712, but not PCM cell 1714. In this manner, individual sections of PCM cell array 1720 can be addressed separately and at different times. While FIG. 17A of PCM cell array 1720 shows only four individually addressable PCM cell sections, the present invention provides for arrays which comprise a plurality of such sections, e.g., more than 5, more than 10, more than 30, more than 50, more than 100, more than 1000, etc., PCM cell sections, each of which can be individually addressable. That is, one specific cell (e.g., 1712) in the array can be addressed separately from each other cell section. In this manner, phase change material that is in contact with the nanowires of the selected PCM cell section is heated (and hence set or re-set as discussed below), while phase change material of other PCM cell sections are not selected/heated.

In further embodiments, the present invention provides methods of setting one or more PCM cells of the present invention. As described throughout, the PCM cell arrays of the present invention can comprise any number of individually addressable PCM cells, each of which comprises a settable phase change material. In order to set the PCM cells, the phase change material is heated to a temperature above the crystalline temperature of the phase change material, but below the melting point of the phase change material, by passing a current through the phase change material, and then slowly cooling the phase change material. The present invention also provides methods of resetting one or more PCM cells of the present invention comprising heating the phase change material of the PCM cell to a temperature above the melting point of the phase change material by passing a current through the phase change element, and then rapidly cooling the element. As each individual PCM cell section is individually addressable, each cell can be set and/or reset individually from any other. The ability to perform any number of these setting/resetting cycles on individual PCM cells using very low currents, in very short amounts of time, provides a very powerful method for writing a phase change material.

The present invention also provides methods of reading the set and reset states of a PCM cell of the present invention. These methods comprise passing a current through the PCM cell, measuring the current through the PCM cell, and determining if the PCM cell is in a reset state (i.e., if the current is below a threshold value) or if it is in a set state (i.e., if the current is above the threshold value). Thus, the present invention provides very rapid methods for both selectively reading a writing large arrays of PCM cells using very low current, in very short times.

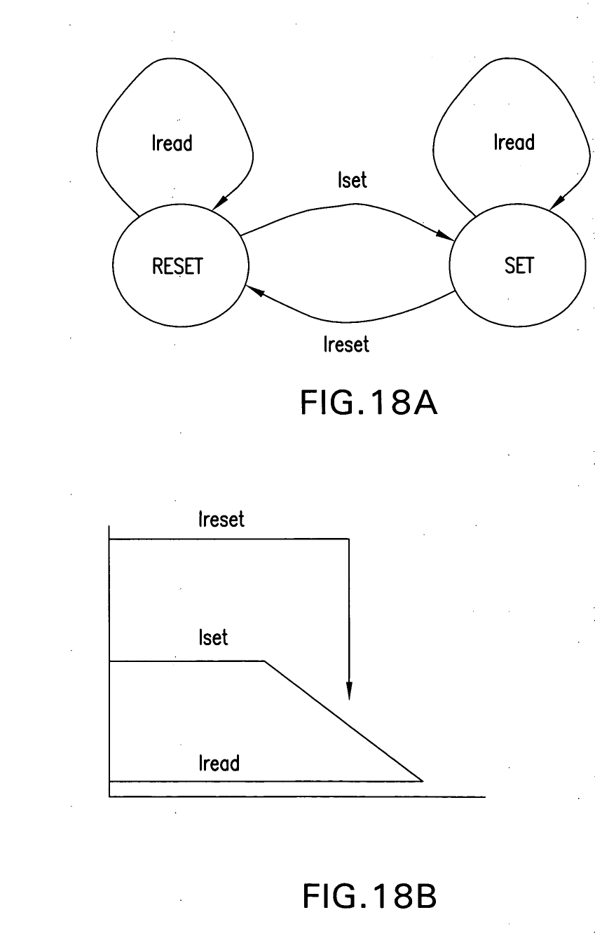

As discussed throughout, in suitable embodiments, the present embodiment utilizes ohmic heating to transition between the two phase states of a phase change material. The set of MOSFETs associated with each PCM cell acts as a switch, and controls the current profile as shown in FIG. 18B, that is allowed to flow from each MOSFET drain 1404, through the phase change material 1706, to the drain connection or bit line 1606 (refer to FIG. 17B). Setting the PCM cell to the crystalline state requires a moderately high drain voltage and/or gate voltage to heat the phase change material to its crystallization point, at which point the voltage is slowly reduced to allow the crystal to form. Resetting the PCM cell to the amorphous glass state requires a higher drain and/or gate voltage to heat the phase change material to its melting point, at which point the voltage is dropped to zero immediately, allowing for the rapid cooling that forms the amorphous glass state.

Phase change materials such as chalcogenide are scalable. That is, smaller, thinner sections of these materials require less heat to reach melting and crystallization points. In the present embodiment, a layer of phase change material on the order of about 1 nm can be sufficient to allow transition between states. State transition switching times are a function of the size of the PCM cell and the current applied. In exemplary embodiments, state transition switching times are on the order of about 5 nanoseconds.

The phase change material layer in the PCM cells acts as the memory storage unit. To read the state of a PCM cell, a much lower current, associated with a much lower drain and/or gate voltage, is used. The current used to read a PCM cell is not high enough to cause sufficient heating, and thus will not change the state of the PCM cell. The source to drain current is inversely proportional to the resistivity of the PCM cell, which is a function of the state of the PCM cell. Resistivity ratios between states in a PCM cell can be on the order of ten to one hundred.

The state diagram for an exemplary PCM cell is given in FIG. 18A. A set state corresponds to the crystalline phase state of a phase change material (e.g., chalcogenide). A reset state corresponds to the amorphous phase state of the phase change material. State transitions are governed by current profiles Iset and Ireset; and an example of Iset and Ireset current profiles is given in FIG. 18B. The energy dissipated to transition to the reset state is higher than the energy dissipated to transition to the set state. To reset, the phase change material is heated to its melting point, e.g., about 600° C. To set, the phase change material, it is heated to its crystallization point, e.g., about 400° C., requiring considerably less heat. Reading the phase change material state can be done with very low currents. Very little heat is dissipated in reading a PCM cell. As a result, the PCM cell remains in its original state during read operations.

An example of current profiles to set, reset, and read a PCM cell are given in FIG. 18B. As an example, Ireset may be much larger than Iset, dissipating more energy for a given amount of time. In another example, Iset may be pulsed for a longer time period than Ireset, dissipating heat faster than the phase change material can radiate heat, until the target melting point temperature is reached.

Exemplary embodiments of the present invention have been presented. The invention is not limited to these examples. These examples are presented herein for purposes of illustration, and not limitation. Alternatives (including equivalents, extensions, variations, deviations, etc., of those described herein) will be apparent to persons skilled in the relevant art(s) based on the teachings contained herein. Such alternatives fall within the scope and spirit of the invention.

All publications, patents and patent applications mentioned in this specification are herein incorporated by reference to the same extent as if each individual publication, patent or patent application was specifically and individually indicated to be incorporated by reference.

1. A method for generating one or more nanostructures of a charge storage layer, comprising:
(a) disposing one or more masking nanoparticles on a charge storage layer substrate, wherein the nanoparticles cover at least a portion of the substrate;
(b) removing uncovered substrate material, thereby forming substrate nanostructures at the site of the masking nanoparticles; and
(c) removing the masking nanoparticles.

2. The method of claim 1, wherein the disposing is on a metal charge storage layer substrate.

3. The method of claim 2, wherein the disposing is on a metal charge storage layer substrate selected from the group consisting of W, WN₂, TaN, and Iridium.

4. The method of claim 1, wherein the disposing comprises spin coating the masking nanoparticles.

5. The method of claim 4, wherein spin coating comprises spin coating Pd, Ni, Ru, Co, or Au nanoparticles.

6. The method of claim 1, wherein the removing in (b) comprises etching the charge layer substrate material, but not the masking nanoparticles.

7. The method of claim 6, wherein the etching comprises anisotropically etching the charge layer substrate material.

8. The method of claim 7, wherein the etching comprises reactive ion etching or electron beam etching.

9. The method of claim 1, wherein the removing the masking nanoparticles in (c) comprises rinsing the substrate surface with a solution.

10. The method of claim 1, wherein the disposing comprises disposing masking nanoparticles that are between about 1-10 nm in diameter, and wherein the nanostructures that are generated are between about 1-10 nm in diameter.

11. The method of claim 1, wherein the disposing comprises disposing masking nanoparticles that are between about 1-5 nm in diameter, and wherein the nanostructures that are generated are between about 1-5 nm in diameter.

12. A method for generating nanoscale cavities in a substrate material, comprising:
(a) disposing a negative photo-resistant layer on a substrate;
(b) disposing one or more masking nanoparticles on the negative photo-resistant layer, wherein the nanoparticles cover at least a portion of the layer;
(c) reacting one or more uncovered portions of the negative photo-resistant layer to form one or more etch masks comprising one or more portions of reacted negative photo-resistant layer and one or more portions of un-reacted negative photo-resistant layer;
(d) removing the masking nanoparticles, thereby revealing the one or more portions of un-reacted negative photo-resistant layer;
(e) removing the un-reacted portions of the photo-resistant layer, thereby revealing one or more exposed substrate sections; and
(f) removing at least a portion of the one or more exposed substrate sections, thereby forming nanoscale cavities in the substrate.

13-24. (canceled)

25. A method for generating one or more nanostructures, comprising:
(a) forming one or more nanoscale cavities in a substrate material according to the method of claim 12;
(b) disposing a filler material in the nanoscale cavities; and
(c) removing excess filler material that is above the plane of the substrate, thereby forming one or more nanostructures in the nanoscale cavities.

26-36. (canceled)

37. A method for generating one or more nanostructures, comprising:
(a) disposing one or more masking nanoparticles on a substrate, wherein the nanoparticles cover at least a portion of the substrate;
(b) removing uncovered substrate material, thereby forming substrate pillars at the portion of the substrate covered by the masking nanoparticles, and forming substrate cavities at a portion of the substrate not covered by the masking nanoparticles;
(c) removing the masking nanoparticles;
(d) disposing an insulating layer on the pillars and at least partially in the cavities, wherein a pit is maintained at the site of the cavities; and
(e) disposing a filler material on the insulating layer, wherein the filler material forms nanostructures confined to the pits.

38-67. (canceled)

68. A nanostructure of a charge storage layer produced by a process comprising:
(a) disposing one or more masking nanoparticles on a charge storage layer substrate, wherein the nanoparticles cover at least a portion of the substrate;
(b) removing uncovered substrate material, thereby forming substrate nanostructures at sites of the masking nanoparticles; and
(c) removing the masking nanoparticles.

69. A nanoscale cavity in a substrate material produced by a process comprising:
(a) disposing a negative photo-resistant layer on a substrate;
(b) disposing one or more masking nanoparticles on the negative photo-resistant layer, wherein the nanoparticles cover at least a portion of the layer;
(c) reacting one or more uncovered portions of the negative photo-resistant layer resistant to form one or more etch masks thereby forming one or more portions of reacted negative photo-resistant layer and one or more portions of un-reacted photo-resistant layer;
(d) removing the masking nanoparticles, thereby revealing the one or more portions of un-reacted negative photo-resistant layer;
(e) removing the un-reacted portions of the photo-resistant layer, thereby revealing one or more exposed substrate sections; and
(f) removing at least a portion of the one or more exposed substrate sections, thereby forming nanoscale cavities in the substrate.

70. A nanostructure produced by a process comprising:
(a) disposing a negative photo-resistant layer on a substrate;
(b) disposing one or more masking nanoparticles on the negative photo-resistant layer, wherein the nanoparticles cover at least a portion of the layer;
(c) reacting one or more uncovered portions of the negative photo-resistant layer resistant to form one or more etch masks thereby forming one or more portions of reacted negative photo-resistant layer and one or more portions of un-reacted photo-resistant layer;
(d) removing the masking nanoparticles, thereby revealing the one or more portions of un-reacted negative photo-resistant layer;
(e) removing the un-reacted portions of the photo-resistant layer, thereby revealing one or more exposed substrate sections;
(f) removing at least a portion of the one or more exposed substrate sections, thereby forming nanoscale cavities in the substrate;
(g) disposing a filler material in the nanoscale cavities; and
(h) removing excess filler material that is above the plane of the substrate, thereby forming one or more nanostructures in the nanoscale cavities.

71. A nanostructure produced by a process comprising:
(a) disposing one or more masking nanoparticles on a substrate, wherein the nanoparticles cover at least a portion of the substrate;
(b) removing uncovered substrate material, thereby forming substrate pillars at the portion of the substrate covered by the masking nanoparticles, and forming substrate cavities at a portion of the substrate not covered by the masking nanoparticles;
(c) removing the masking nanoparticles;
(d) disposing an insulating layer on the pillars and at least partially in the cavities, wherein a pit is maintained at the site of the cavities; and
(e) disposing a filler material on the insulating layer, wherein the filler material forms nanostructures confined to the pits.

72. A plurality of metallic nanostructures, wherein:
the nanostructures comprise diameters between about 1 nanometer and about 10 nanometers;
the nanostructures comprise diameters with size distributions no greater than about 15% of a mean diameter of the nanostructures;
a center-to-center spacing between adjacent nanostructures is between about 1 nanometer and about 10 nanometers; and
a center-to-center spacing between adjacent nanostructures is controlled to comprise a variance of about 10%.

73. (canceled)

74. (canceled)

75. A field effect transistor, comprising:
a source region and a drain region formed in a semiconductor material;
a channel region disposed between the source region and the drain region;
an insulating layer of electrically insulating material disposed over the channel region;
a floating gate layer of electrically conducting material disposed over the insulating layer;
a layer of electrically insulating material disposed over the floating gate layer; and
a gate electrode overlying the layer of insulating material,
wherein, the floating gate layer comprises a plurality of discrete nanostructures of claim 72.

76. A field effect transistor, comprising:
a source region and a drain region formed in a semiconductor material;
a channel region disposed between the source region and the drain region;
an insulating layer of electrically insulating material disposed over the channel region;
a floating gate layer of electrically conducting material disposed over the insulating layer;
a layer of electrically insulating material disposed over the floating gate layer; and
a gate electrode overlying the layer of insulating material,
wherein the floating gate layer comprises a plurality of discrete electrically conducting nanostructures prepared by a process comprising:
(a) disposing one or more masking nanoparticles on an electrically conducting substrate, wherein the nanoparticles cover at least a portion of the substrate;
(b) removing uncovered substrate material, thereby forming electrically conducting substrate nanostructures at sites of the masking nanoparticles; and
(c) removing the masking nanoparticles.

77. A field effect transistor, comprising:
a source region and a drain region formed in a semiconductor material;
a channel region disposed between the source region and the drain region;
an insulating layer of electrically insulating material disposed over the channel region;
a floating gate layer of electrically conducting material disposed in the insulating layer;
a layer of electrically insulating material disposed over the floating gate layer; and
a gate electrode overlying the layer of insulating material,
wherein, the floating gate layer comprises a plurality of discrete electrically conducting nanostructures prepared by a process comprising:
(a) disposing a negative photo-resistant layer on the insulating layer;
(b) disposing one or more masking nanoparticles on the negative photo-resistant layer, wherein the nanoparticles cover at least a portion of the negative photo-resistant layer;
(c) reacting one or more uncovered portions of the negative photo-resistant layer resistant to form one or more etch masks comprising one or more portions of reacted negative photo-resistant layer and one or more portions of un-reacted photo-resistant layer;
(d) removing the masking nanoparticles, thereby revealing the one or more portions of un-reacted negative photo-resistant layer;
(e) removing the un-reacted portions of the photo-resistant layer, thereby revealing one or more exposed insulating layer sections; and
(f) removing at least a portion of the one or more exposed insulating layer sections, thereby forming nanoscale cavities in the insulating layer;
(g) disposing an electrically conducting filler material in the nanoscale cavities; and
(h) removing excess filler material that is above the plane of the insulating layer, thereby forming one or more electrically conducting nanostructures in the nanoscale cavities.

78. A field effect transistor, comprising:
a source region and a drain region formed in a semiconductor material;
a channel region disposed between the source region and the drain region;
an insulating layer of electrically insulating material disposed over the channel region;
a floating gate layer of electrically conducting material disposed in the insulating layer;
a layer of electrically insulating material disposed over the floating gate layer; and
a gate electrode overlying the layer of insulating material,
wherein, the floating gate layer comprises a plurality of discrete electrically conducting nanostructures prepared by a process comprising:
(a) disposing one or more masking nanoparticles on a substrate, wherein the nanoparticles cover at least a portion of the substrate;
(b) removing uncovered substrate material, thereby forming substrate pillars at the portion of the substrate covered by the masking nanoparticles, and forming substrate cavities at a portion of the substrate not covered by the masking nanoparticles;
(c) removing the masking nanoparticles;
(d) disposing an insulating layer of electrically insulating material on the pillars and at least partially in the cavities, wherein a pit is maintained at the site of the cavities; and
(e) disposing an electrically conducting filler material on the insulating layer, wherein the filler material forms electrically conducting nanostructures confined to the pits.

79. A method for generating nanoscale cavities in a substrate material, comprising:
(a) providing a support structure;
(b) disposing one or more masking nanoparticles on the support structure;
(c) disposing a substrate material on the masking nanoparticles and the support structure, thereby covering the masking nanoparticles;
(d) removing at least a portion of the substrate material, thereby revealing at least a portion of the masking nanoparticles;
(e) removing the masking nanoparticles, thereby forming nanoscale cavities in the substrate material.

80-103. (canceled)

104. A method for generating a nanoscale phase change layer, comprising:
(a) forming one or more nanoscale cavities in a substrate material according to the method of claim 79; and
(b) disposing a phase change material in at least the nanoscale cavities.

105. The method of claim 104, wherein the disposing comprises chemical vapor deposition of the nanoscale phase change layer.

106-108. (canceled)

109. A method for generating a phase change memory (PCM) cell, comprising:
(a) forming one or more nanoscale cavities in a substrate material according to the method of claim 79;
(b) disposing a phase change material in at least the nanoscale cavities; and
(c) electrically connecting the phase change material to an electrical contact, thereby forming a PCM cell.

110-119. (canceled)

120. A method for generating one or more nanowires, comprising:
(a) providing a substrate material;
(b) disposing one or more masking nanoparticles on the substrate, wherein the nanoparticles cover at least a portion of the substrate;
(c) removing uncovered substrate material, thereby forming substrate nanowires at the site of the masking nanoparticles, wherein the nanowires are greater than 20 nm in length; and
(d) removing the masking nanoparticles.

121-130. (canceled)

131. A method for generating one or more transistor switches, comprising:
(a) providing a substrate material;
(b) disposing one or more masking nanoparticles on the substrate, wherein the nanoparticles cover at least a portion of the substrate;
(c) removing uncovered substrate material, thereby forming substrate nanowires at the site of the masking nanoparticles;
(d) removing the masking nanoparticles;
(e) growing a first oxide layer on the substrate and substrate nanowires;
(f) disposing a filler material;
(g) removing a portion of the filler material, whereby a cavity is formed in the filler material between substrate nanowires;
(h) disposing a second oxide layer; and
(i) removing the first and the second oxide layer, whereby a portion of the substrate nanowires are exposed, and whereby the filler material is not exposed.

132-161. (canceled)

162. A method for generating an array of electrically connected phase change memory (PCM) cells, comprising:
(a) forming two or more transistor switches according to the method of claim 131;
(b) generating masked and unmasked alternating lines, wherein the lines comprise substrate nanowires and filler material;
(c) removing unmasked alternating lines, thereby forming troughs between masked lines;
(d) disposing an insulating material in the troughs;
(e) exposing a portion of the substrate nanowires;
(f) electrically connecting the filler material in each line;
(g) disposing a phase change material layer; and
(h) electrically connecting one or more substrate nanowires in each line.

163-170. (canceled)

171. A transistor switch, comprising:
(a) one or more transistor nanowires;
(b) an electrically conductive gate material surrounding the nanowires;
(c) an insulating material separating the nanowires from the electrically conductive gate material;
(d) an electrical connection to the gate material; and
(e) an electrical connection to the nanowires.

172-175. (canceled)

176. A phase change memory (PCM) cell, comprising:
(a) one or more transistor nanowires;
(b) an electrically conductive gate material surrounding the nanowires;
(c) a phase change material layer contacting at least a portion of at least one nanowire;
(d) an insulating material separating the nanowires from the electrically conductive gate material, and separating the electrically conductive gate material from the phase change material layer; and
(e) an electrical connection to the phase change material layer.

177-185. (canceled)
